(19) United States
(12) Patent Application Publication
(10) Pub. No.: US 2024/0179981 A1
(43) Pub. Date: May 30, 2024

(54) DISPLAY DEVICE

(71) Applicant: LG Display Co., Ltd., Seoul (KR)

(72) Inventor: Chanwoo LEE, Seoul (KR)

(21) Appl. No.: 18/474,723

(22) Filed: Sep. 26, 2023

(30) Foreign Application Priority Data
Nov. 29, 2022 (KR) 10-2022-0163053

(51) Int. Cl. H10K 59/131; H10K 59/124

(52) U.S. Cl. CPC H10K 59/131; H10K 59/124

(57) ABSTRACT

According to the present disclosure, a display device includes a lower substrate, and is formed of one of transparent conducting oxide and an oxide semiconductor, an inorganic layer disposed on the lower substrate, a planarization layer disposed on the inorganic layer, a bank disposed on the planarization layer, an adhesive layer disposed on the inorganic layer, the planarization layer, and the bank, and an upper substrate disposed on the adhesive layer, and the bank includes a first bank disposed in an area overlapping the lower substrate and a second bank disposed so as to enclose side surfaces of the first bank, the inorganic layer, the planarization layer, and the lower substrate. Accordingly, a moisture permeation characteristic of the display device may be improved and the crack generated in the outer peripheral area may be reduced.

### CROSS-REFERENCE TO RELATED APPLICATIONS

This application claims the priority of Korean Patent Application No. 2022-0163053 filed on Nov. 29, 2022, in the Korean Intellectual Property Office, the disclosure of which is incorporated herein by reference.

### BACKGROUND

### Technical Field

The present disclosure relates to a display device.

### Description of the Related Art

As display devices which are used for a monitor of a computer, a television, or a cellular phone, there are an organic light emitting display (OLED) device which is a self-emitting device and a liquid crystal display (LCD) device which includes a separate light source.

An applicable range of the display device is diversified to personal digital assistants as well as monitors of computers and televisions and a display device with a large display area and a reduced volume and weight is being studied.

Further, recently, a flexible display device which is manufactured by forming a display element and a wiring line on a flexible substrate such as plastic which is a flexible material so as to be capable of displaying images even in a folded or rolled state is getting attention as a next generation display device.

### BRIEF SUMMARY

This disclosure relates to a display device having a plastic substrate at an outer peripheral area, which reduces potential cracks generated at the outer peripheral area. The present disclosure provides a display device which uses one of a transparent conducting oxide layer and an oxide semiconductor layer as a substrate, instead of a plastic substrate.

The present disclosure provides a display device in which cracks of a substrate and an inorganic layer generated at an outer peripheral portion of the display device are reduced.

The present disclosure provides a display device in which a seal member is removed to reduce a bezel area.

Technical features and benefits of the present disclosure are not limited to the above-mentioned objects, and other objects, which are not mentioned above, can be clearly understood by those skilled in the art from the following descriptions.

According to an aspect of the present disclosure, a display device includes a lower substrate which includes an active area including a plurality of sub pixels and a non-active area enclosing the active area and is formed of one of transparent conducting oxide and an oxide semiconductor; an outer pattern which is disposed so as to enclose an outer periphery of the lower substrate and is formed of an organic material; an inorganic layer disposed on the lower substrate and the outer pattern; and a plurality of light emitting diodes disposed on the inorganic layer in the plurality of sub pixels. Accordingly, cracks of the substrate and the inorganic layer generated in the outer peripheral portion of the display device may be reduced.

Other detailed matters of the exemplary embodiments are included in the detailed description and the drawings.

According to the present disclosure, a transparent conductive oxide layer and an oxide semiconductor layer are used as a substrate of the display device to easily control a moisture permeability and improve a flexibility.

According to the present disclosure, an outer pattern is disposed at the outside of the lower substrate to reduce cracks generated in the outer peripheral area of the display device.

According to the present disclosure, an outer pattern of the display device is disposed so as to overlap a gate driver to reduce a parasitic capacitance of the display device.

According to the present disclosure, a seal member disposed on an outer peripheral portion of the display device is removed to reduce a non-active area.

According to the present disclosure, a colored polyimide (PI) material is used for the outer pattern of the display device to reduce a manufacturing cost of the display device.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure;

FIG. 2 is a schematic cross-sectional view of a display device according to an exemplary embodiment of the present disclosure;

FIG. 3 is a circuit diagram of a sub pixel of a display device according to an exemplary embodiment of the present disclosure;

FIG. 4 is an enlarged plan view of a display device according to an exemplary embodiment of the present disclosure;

FIG. 5 is a cross-sectional view taken along the line V-V′ of FIG. 4;

FIG. 6A is a cross-sectional view for explaining a manufacturing process of a display device according to an exemplary embodiment of the present disclosure;

FIG. 6B is a cross-sectional view of a display device according to an exemplary embodiment of the present disclosure;

FIG. 7 is an enlarged view of an area A of FIG. 1;

FIG. 8A is a cross-sectional view for explaining a manufacturing process of a display device according to an exemplary embodiment of the present disclosure;

FIG. 8B is a cross-sectional view of a display device according to an exemplary embodiment of the present disclosure;

FIG. 9A is a cross-sectional view for explaining a manufacturing process of a display device according to an exemplary embodiment of the present disclosure;

FIG. 9B is a cross-sectional view of a display device according to an exemplary embodiment of the present disclosure;

FIG. 10A is a cross-sectional view for explaining a manufacturing process of a display device according to an exemplary embodiment of the present disclosure;

FIG. 10B is a cross-sectional view of a display device according to another exemplary embodiment of the present disclosure;

FIG. 11A is a cross-sectional view for explaining a manufacturing process of a display device according to another exemplary embodiment of the present disclosure;

FIG. 11B is a cross-sectional view of a display device according to still another exemplary embodiment of the present disclosure;

FIG. 12A is a cross-sectional view for explaining a manufacturing process of a display device according to still another exemplary embodiment of the present disclosure;

FIG. 12B is a cross-sectional view of a display device according to still another exemplary embodiment of the present disclosure;

FIG. 13A is a cross-sectional view for explaining a manufacturing process of a display device according to still another exemplary embodiment of the present disclosure;

FIG. 13B is a cross-sectional view of a display device according to still another exemplary embodiment of the present disclosure;

FIG. 14A is a cross-sectional view for explaining a manufacturing process of a display device according to still another exemplary embodiment of the present disclosure; and

FIG. 14B is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including.” “having.” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

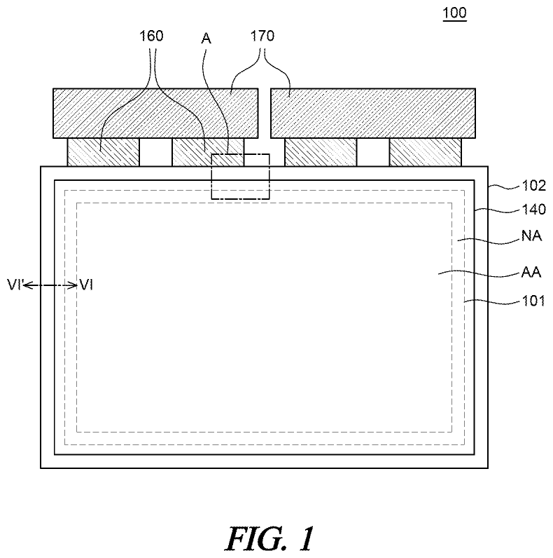

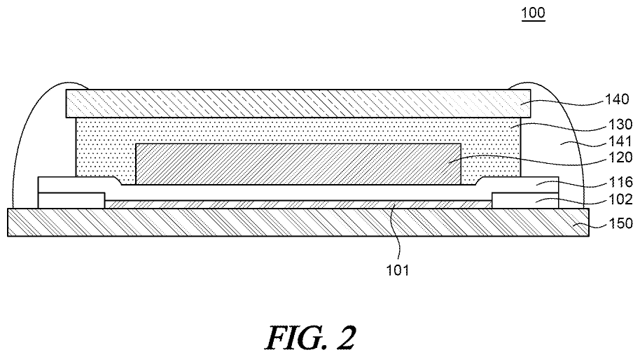

FIG. 1 is a plan view of a display device according to an exemplary embodiment of the present disclosure. FIG. 2 is a schematic cross-sectional view of a display device according to an exemplary embodiment of the present disclosure. For the convenience of description, in FIG. 1, among various components of the display device 100, only a lower substrate 101, an outer pattern 102, an upper substrate 140, a seal member 141, a plurality of flexible films 160, and a plurality of printed circuit boards 170 are illustrated.

Referring to FIGS. 1 and 2, the lower substrate 101 is a support member which supports other components of the display device 100. The lower substrate 101 may be formed of any one of a transparent conducting oxide and an oxide semiconductor. For example, the lower substrate 101 may be formed of a transparent conducting oxide (TCO), such as indium tin oxide (ITO), indium zinc oxide (IZO), or indium tin zinc oxide (ITZO).

Further, the lower substrate 101 may be formed of an oxide semiconductor material formed of indium (In) and gallium (Ga), for example, a transparent oxide semiconductor such as indium gallium zinc oxide (IGZO), indium gallium oxide (IGO), and indium tin zinc oxide (ITZO). However, a type of a material of the transparent conducting oxide and the oxide semiconductor is illustrative so that the lower substrate 101 may be formed by another transparent conducting oxide and oxide semiconductor material which have not been described in the specification, but is not limited thereto.

In the meantime, the lower substrate 101 may be formed by depositing the transparent conducting oxide or an oxide semiconductor with a very thin thickness. Therefore, as the lower substrate 101 is formed to have a very thin thickness, the lower substrate may have a flexibility. A display device 100 including the lower substrate 101 having a flexibility may be implemented as a flexible display device 100 which displays an image even in a folded or rolled state. For example, when the display device 100 is a foldable display device, the lower substrate 101 may be folded or unfolded with respect to a folding axis. As another example, when the display device 100 is a rollable display device, the display device may be stored by being rolled around the roller. Accordingly, the display device 100 according to the exemplary embodiment of the present disclosure uses the lower substrate 101 having a flexibility to be implemented as a flexible display device 100 like a foldable display device or a rollable display device.

Further, the display device 100 according to the exemplary embodiment of the present disclosure uses the lower substrate 101 formed of a transparent conducting oxide or an oxide semiconductor to perform a laser lift off (LLO) process. The LLO process refers to a process of separating a temporary substrate SUB below the lower substrate 101 from the lower substrate 101 using laser during the manufacturing process of a display device 100. Accordingly, the lower substrate 101 is a layer for more easily performing the LLO process so that it may be referred to as a functional thin film, a functional thin film layer, or a functional substrate. The LLO process will be described in more detail below.

The lower substrate 101 includes an active area AA and a non-active area NA.

The active area AA is an area where images are displayed. In the active area AA, a pixel unit 120 includes a plurality of sub pixels may be disposed to display images. For example, the pixel unit 120 includes a plurality of sub pixels including a light emitting diode and a driving circuit to display images.

The non-active area NA is an area where no image is displayed and various wiring lines and driving ICs for driving the sub pixels disposed in the active area AA are disposed. For example, in the non-active area NA, various driving ICs, such as a gate driver IC and a data driver IC, may be disposed.

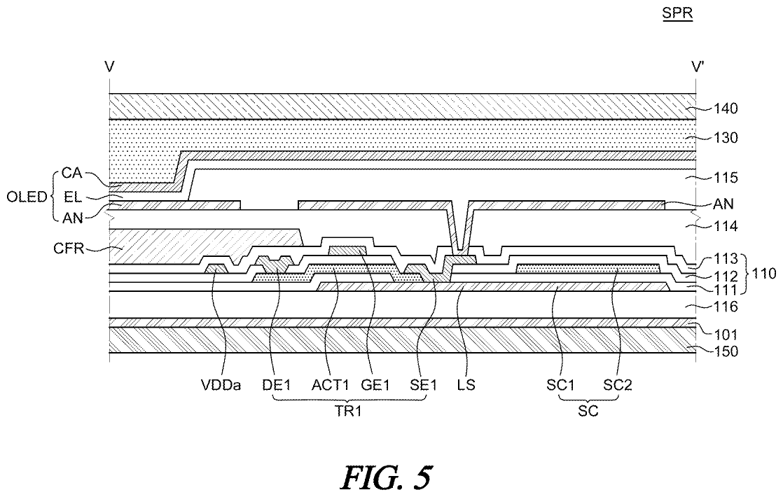

An outer pattern 102 is disposed so as to enclose the outer periphery of the lower substrate 101. The outer pattern 102 will be described in more detail below with reference to FIGS. 5 to 9B.

The plurality of flexible films 160 is disposed at one end of the outer pattern 102. The plurality of flexible films 160 is electrically connected to one end of the outer pattern 102. The plurality of flexible films 160 is films in which various components are disposed on a base film having malleability to supply a signal to the plurality of sub pixels of the active area AA. One ends of the plurality of flexible films 160 are disposed in the non-active area NA of the outer pattern 102 to supply a data voltage to the plurality of sub pixels of the active area AA. In the meantime, even though four flexible films 160 are illustrated in FIG. 1, the number of flexible films 160 may vary depending on the design, but is not limited thereto.

In the meantime, a driving IC such as a gate driver IC or a data driver IC may be disposed on the plurality of flexible films 160. The driving IC is a component which processes data for displaying images and a driving signal for processing the data. The driving IC may be disposed by a chip on glass (COG), a chip on film (COF), or a tape carrier package (TCP) technique depending on a mounting method. In the present specification, for the convenience of description, it is described that the driving IC is mounted on the plurality of flexible films 160 by a chip on film technique, but is not limited thereto.

The printed circuit board 170 is connected to the plurality of flexible films 160. The printed circuit board 170 is a component which supplies signals to the driving IC. Various components may be disposed in the printed circuit board 170 to supply various driving signals such as a driving signal or a data voltage to the driving IC. In the meantime, even though two printed circuit boards 170 are illustrated in FIG. 1, the number of printed circuit boards 170 may vary depending on the design and is not limited thereto.

Referring to FIG. 2, a lower buffer layer 116 is disposed on the lower substrate 101 and the outer pattern 102. The lower buffer layer 116 will be described in more detail below with reference to FIGS. 5 to 9B.

The pixel unit 120 is disposed on the lower buffer layer 116. The pixel unit 120 may be disposed so as to correspond to the active area AA. The pixel unit 120 is a component which includes a plurality of sub pixels to display images. The plurality of sub pixels of the pixel unit 120 which configure the active area AA and a light emitting diode and a driving circuit may be disposed in each of the plurality of sub pixels. For example, the light emitting diode of each of the plurality of sub pixels may include an organic light emitting diode including an anode, an organic emission layer, and a cathode or an LED including an N-type and a P-type semiconductor layers and an emission layer, but is not limited thereto. The driving circuit for driving the plurality of sub pixels may include a driving element such as a thin film transistor or a storage capacitor, but is not limited thereto. Hereinafter, for the convenience of description, it is assumed that the light emitting diode of each of the plurality of sub pixels is an organic light emitting diode, but it is not limited thereto.

In the meantime, the display device 100 may be configured by a top emission type or a bottom emission type, depending on an emission direction of light which is emitted from the light emitting diode.

According to the top emission type, light emitted from the light emitting diode is emitted to an upper portion of the lower substrate 101 on which the light emitting diode is disposed. In the case of the top emission type, a reflective layer may be formed below the anode to allow the light emitted from the organic light emitting diode to travel to the upper portion of the lower substrate 101, that is, toward the cathode.

According to the bottom emission type, light emitted from the light emitting diode is emitted to a lower portion of the lower substrate 101 on which the light emitting diode is disposed. In the case of the bottom emission type, the anode may be formed only of a transparent conductive material and the cathode may be formed of the metal material having a high reflectance to allow the light emitted from the light emitting diode to travel to the lower portion of the lower substrate 101.

Hereinafter, for the convenience of description, the description will be made by assuming that the display device 100 according to an exemplary embodiment of the present disclosure is a bottom emission type display device, but it is not limited thereto.

An adhesive layer 130 is disposed to cover the pixel unit 120. The adhesive layer 130 serves to bond the lower substrate 101 and the upper substrate 140 and encloses the pixel unit 120 to protect the light emitting diode of the pixel unit 120 from external moisture, oxygen, and impacts. The adhesive layer 130 may be configured by a face seal type. For example, the adhesive layer 130 may be formed by forming ultraviolet or thermosetting sealant on the entire surface of the pixel unit 120. However, the structure of the adhesive layer 130 may be formed by various methods and materials, but is not limited thereto.

In the meantime, the upper substrate 140 which has a high modulus and is formed of a metal material having a strong corrosion resistance is disposed on the adhesive layer 130. For example, the upper substrate 140 may be formed of a material having a high modulus of approximately 200 to 900 MPa. The encapsulation substrate may be formed of a metal material, which has a high corrosion resistance and is easily processed in the form of a foil or a thin film, such as aluminum (Al), nickel (Ni), chromium (Cr), iron (Fe), and an alloy material of nickel. Therefore, as the upper substrate 140 is formed of a metal material, the upper substrate 140 may be implemented as an ultra-thin film and provide a strong resistance against external impacts and scratches.

A polarizer 150 is disposed below the lower substrate 101 and the outer pattern 102. The polarizer 150 selectively transmits light to reduce the reflection of external light which is incident onto the lower substrate 101. Specifically, in the display device 100, various metal materials which are applied to semiconductor devices, wiring lines, and light emitting diodes are formed on the lower substrate 101 and the outer pattern 102. Therefore, the external light incident onto the lower substrate 101 may be reflected from the metal material so that the visibility of the display device 100 may be reduced due to the reflection of the external light. At this time, the polarizer 150 which suppresses the reflection of external light is disposed below the lower substrate 101 and the outer pattern 102 to increase outdoor visibility of the display device 100. However, the polarizer 150 may be omitted depending on an implementation example of the display device 100.

Even though not illustrated in the drawing, a barrier film may be disposed below the lower substrate 101 and the outer pattern 102 together with the polarizer 150. The barrier film reduces the permeation of the moisture and oxygen outside the lower substrate 101 into the lower substrate 101 and the outer pattern 102 to protect the pixel unit 120 including a light emitting diode. However, the barrier film may also be omitted depending on an implementation example of the display device 100, but it is not limited thereto.

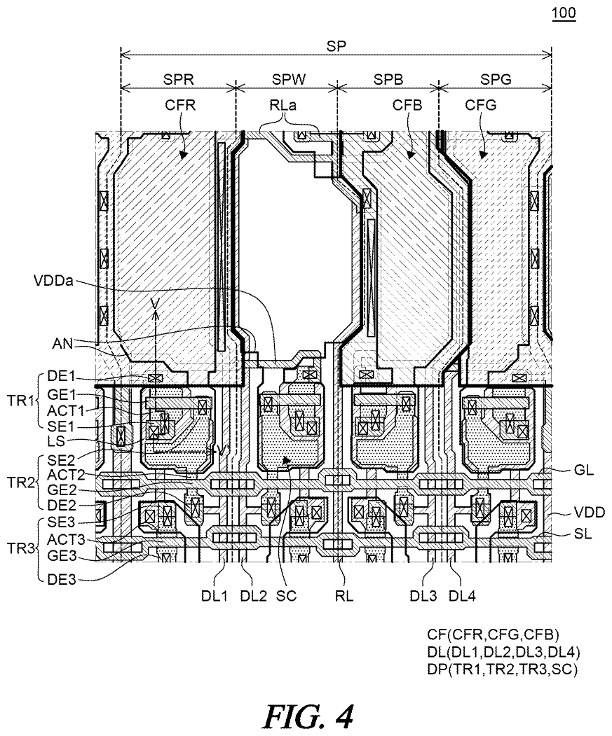

The seal member 141 is disposed so as to enclose side surfaces of the pixel unit 120, the adhesive layer 130, and the upper substrate 140. The seal member 140 is disposed in the non-active area NA on the outer pattern 102 and may be disposed to enclose the pixel unit 120 disposed in the active area AA and a side surface of the upper substrate 140. The seal member 141 will be described below in more detail with reference to FIGS. 4 to 9B.

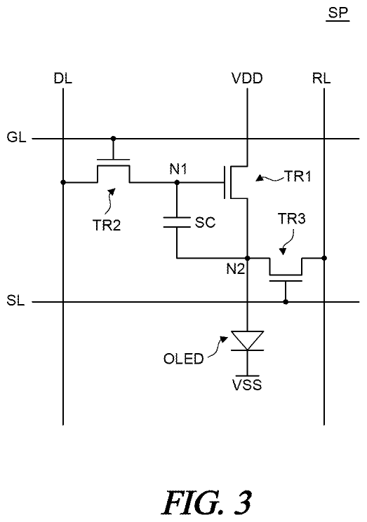

Hereinafter, the plurality of sub pixels of the pixel unit 120 will be described in more detail with reference to FIGS. 3 to 6B.

FIG. 3 is a circuit diagram of a sub pixel of a display device according to an exemplary embodiment of the present disclosure.

Referring to FIG. 3, the driving circuit for driving the light emitting diode OLED of the plurality of sub pixels SP includes a first transistor TR1, a second transistor TR2, a third transistor TR3, and a storage capacitor SC. In order to drive the driving circuit, a plurality of wiring lines including a gate line GL, a data line DL, a high potential power line VDD, a sensing line SL, and a reference line RL is disposed on the lower substrate 101.

Each of the first transistor TR1, the second transistor TR2, and the third transistor TR3 included in the driving circuit of one sub pixel SP includes a gate electrode, a source electrode, and a drain electrode.

The first transistor TR1, the second transistor TR2, and the third transistor TR3 may be P-type thin film transistors or N-type thin film transistors. For example, since in the P-type thin film transistor, holes flow from the source electrode to the drain electrode, the current may flow from the source electrode to the drain electrode. Since in the N-type thin film transistor, electrons flow from the source electrode to the drain electrode, the current may flow from the drain electrode to the source electrode. Hereinafter, the description will be made under the assumption that the first transistor TR1, the second transistor TR2, and the third transistor TR3 are N-type thin film transistors in which the current flows from the drain electrode to the source electrode, but the present disclosure is not limited thereto.

The first transistor TR1 includes a first active layer, a first gate electrode, a first source electrode, and a first drain electrode. The first gate electrode is connected to a first node N1, the first source electrode is connected to the anode of the light emitting diode OLED, and the first drain electrode is connected to the high potential power line VDD. When a voltage of the first node N1 is higher than a threshold voltage, the first transistor TR1 is turned on and when the voltage of the first node N1 is lower than the threshold voltage, the first transistor TR1 may be turned off. When the first transistor TR1 is turned on, a driving current may be transmitted to the light emitting diode OLED by means of the first transistor TR1. Therefore, the first transistor TR1 which controls the driving current transmitted to the light emitting diode OLED may also be referred to as a driving transistor.

The second transistor TR2 includes a second active layer, a second gate electrode, a second source electrode, and a second drain electrode. The second gate electrode is connected to the gate line GL, the second source electrode is connected to the first node N1, and the second drain electrode is connected to the data line DL. The second transistor TR2 may be turned on or off based on a gate voltage from the gate line GL. When the second transistor TR2 is turned on, a data voltage from the data line DL may be charged in the first node N1. Therefore, the second transistor TR2 which is turned on or turned off by the gate line GL may also be referred to as a switching transistor.

The third transistor TR3 includes a third active layer, a third gate electrode, a third source electrode, and a third drain electrode. The third gate electrode is connected to the sensing line SL, the third source electrode is connected to the second node N2, and the third drain electrode is connected to the reference line RL. The third transistor TR3 may be turned on or off based on a sensing voltage from the sensing line SL. When the third transistor TR3 is turned on, a reference voltage from the reference line RL may be transmitted to the second node N2 and the storage capacitor SC. Therefore, the third transistor TR3 may also be referred to as a sensing transistor.

In the meantime, even though in FIG. 3, it is illustrated that the gate line GL and the sensing line SL are separate wiring lines, the gate line GL and the sensing line SL may also be implemented as one wiring line, but it is not limited thereto.

The storage capacitor SC is connected between the first gate electrode and the first source electrode of the first transistor TR1. That is, the storage capacitor SC may be connected between the first node N1 and the second node N2. The storage capacitor SC maintains a potential difference between the first gate electrode and the first source electrode of the first transistor TR1 while the light emitting diode OLED emits light, so that a constant driving current may be supplied to the light emitting diode OLED. The storage capacitor SC includes a plurality of capacitor electrodes and for example, one of the plurality of capacitor electrodes is connected to the first node N1 and another one may be connected to the second node N2.

The light emitting diode OLED includes an anode, an emission layer, and a cathode. The anode of the light emitting diode OLED is connected to the second node N2 and the cathode is connected to the low potential power line VSS. The light emitting diode OLED is supplied with a driving current from the first transistor TR1 to emit light.

In the meantime, in FIG. 3, it is described that the driving circuit of the sub pixel SP of the display device 100 according to the exemplary embodiment of the present disclosure has a 3T1C structure including three transistors and one storage capacitor SC. However, the number and a connection relationship of the transistors and the storage capacitor may vary in various ways depending on the design and are not limited thereto.

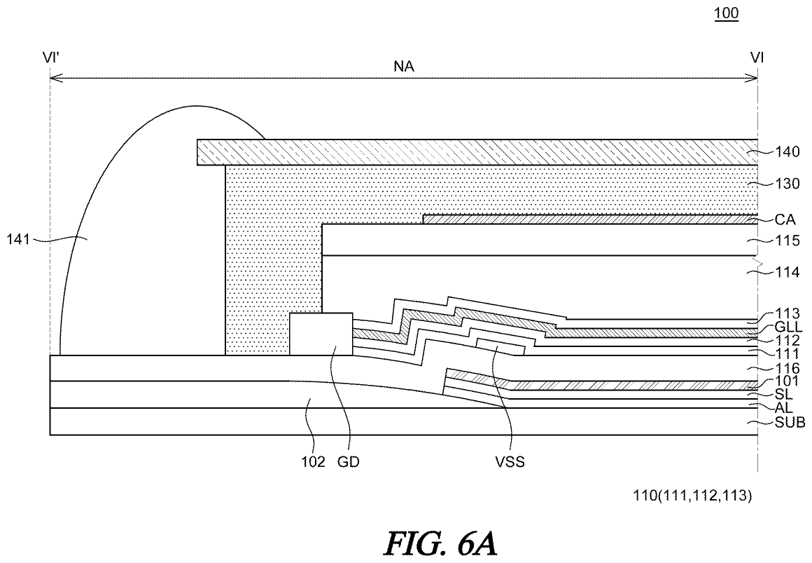

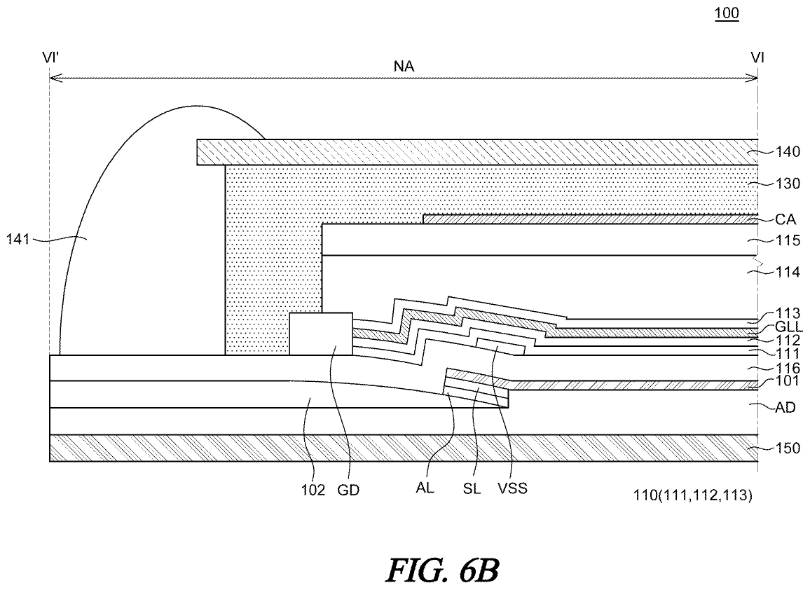

FIG. 4 is an enlarged plan view of a display device according to an exemplary embodiment of the present disclosure. FIG. 5 is a cross-sectional view taken along the line V-V′ of FIG. 4. FIG. 6A is a cross-sectional view for explaining a manufacturing process of a display device according to an exemplary embodiment of the present disclosure. FIG. 6B is a cross-sectional view of a display device according to an exemplary embodiment of the present disclosure. FIG. 4 is an enlarged plan view of a red sub pixel SPR, a white sub pixel SPW, a blue sub pixel SPB, and a green sub pixel SPG which configure one pixel. In FIG. 4, for the convenience of description, the bank 115 is omitted and edges of the plurality of color filters CF are illustrated with a bold solid line. FIGS. 6A and 6B are cross-sectional views taken along the line VI-VI′ of FIG. 1. FIG. 6A is a cross-sectional view illustrating a state before an LLO process of a manufacturing process of a display device according to an exemplary embodiment of the present disclosure. Referring to FIGS. 4 and 6B, the display device 100 according to the exemplary embodiment of the present disclosure includes a lower substrate 101, a lower buffer layer 116, an inorganic layer 110, an outer pattern 102, a gate driver GD, a planarization layer 114, a bank 115, a first transistor TR1, a second transistor TR2, a third transistor TR3, a storage capacitor SC, a light emitting diode OLED, a gate line GL, a sensing line SL, a data line DL, a reference line RL, a high potential power line VDD, a plurality of color filters CF, an adhesive layer 130, an upper substrate 140, and a seal member 141.

Referring to FIG. 4, the plurality of sub pixels SP includes a red sub pixel SPR, a green sub pixel SPG, a blue sub pixel SPB, and a white sub pixel SPW. For example, the red sub pixel SPR, the white sub pixel SPW, the blue sub pixel SPB, and the green sub pixel SPG may be sequentially disposed along a row direction. However, the placement order of the plurality of sub pixels SP is not limited thereto.

Each of the plurality of sub pixels SP includes an emission area and a circuit area. The emission area is an area where one color light is independently emitted and the light emitting diode OLED may be disposed therein. Specifically, in an area where the plurality of color filters CF and the anode AN overlap, an area which is exposed from the bank 115 to allow light emitted from the light emitting diode OLED to travel to the outside may be defined as an emission area. For example, referring to FIGS. 4 and 5 together, an emission area of the red sub pixel SPR may be an area exposed from the bank 115 in an area in which the red color filter CFR and the anode AN overlap. An emission area of the green sub pixel SPG may be an area exposed from the bank 115 in an area in which the green color filter CFG and the anode AN overlap. An emission area of the blue sub pixel SPB may be an area exposed from the bank 115 in an area in which the blue color filter CFB and the anode AN overlap. At this time, in an emission area of the white sub pixel SPW in which a separate color filter CF is not disposed, an area overlapping a part of the anode AN exposed from the bank 115 may be a white emission area which emits white light.

The circuit area is an area excluding the emission area and a driving circuit DP for driving the plurality of light emitting diodes OLED and a plurality of wiring lines which transmits various signals to the driving circuit DP may be disposed. The circuit area in which the driving circuit DP, the plurality of wiring lines, and the bank 115 are disposed may be a non-emission area. For example, in the circuit area, the driving circuit DP including the first transistor TR1, the second transistor TR2, the third transistor TR3, and the storage capacitor SC, a plurality of high potential power lines VDD, a plurality of data lines DL, a plurality of reference lines RL, a plurality of gate lines GL, a sensing line SL, and the bank 115 may be disposed.

Referring to FIGS. 3 to 6B together, the outer pattern 102 may be disposed so as to enclose the outer periphery of the lower substrate 101. Therefore, the outer pattern 102 may be disposed at the edge of the display device 100. At this time, the outer pattern 102 may overlap a part of the lower substrate 101. For example, the outer pattern 102 and the lower substrate 101 may overlap so that a part of the lower substrate 101 may be disposed on the outer pattern 102.

The outer pattern 102 may be formed of an organic material and for example, the outer pattern 102 may be formed of polyimide (PI) or formed of colored polyimide. Accordingly, an area of the display device 100 in which the outer pattern 102 is disposed may be opaque.

The outer pattern 102 may be disposed to have a thickness of 1700 Å to 5500 Å in an area overlapping the edge of the temporary substrate SUB and the thickness of the outer pattern 102 may be adjusted by controlling a viscosity of a material which configures the outer pattern 102.

The lower buffer layer 116 is disposed below the lower substrate 101 and the outer pattern 102. The lower buffer layer 116 may be disposed to cover an end of the lower substrate 101. Further, the end of the lower buffer layer 116 may be disposed at the outside more than the end of the upper substrate 140. Therefore, the end of the lower buffer layer 116 overlaps an end of the outer pattern 102, but is not limited thereto. Therefore, the end of the lower buffer layer 116 may be disposed between the end of the upper substrate 140 and the end of the outer pattern 102 so that the lower buffer layer 116 is disposed on a part of the outer pattern 102.

The lower buffer layer 116 may suppress moisture and/or oxygen which penetrates from the outside of the lower substrate 101 from being spread. The moisture permeation characteristic of the display device 100 may be controlled by controlling a thickness or a lamination structure of the lower buffer layer 116. Further, the lower buffer layer 116 may suppress a short problem caused when the lower substrate 101 formed of a transparent conducting oxide or an oxide semiconductor is in contact with the other configurations such as a pixel unit 120. The lower buffer layer 116 may be formed of an inorganic material, for example, may be configured by a single layer or a plurality of layers of silicon oxide (SiOx) or silicon nitride (SiNx), but is not limited thereto.

The plurality of high potential power lines VDD, the plurality of data lines DL, the plurality of reference lines RL, and the light shielding layer LS are disposed on the lower buffer layer 116.

The plurality of high potential power lines VDD, the plurality of data lines DL, the plurality of reference lines RL, and the light shielding layer LS are disposed on the same layer on the lower substrate 101 and may be formed of the same conductive material. For example, the plurality of high potential power lines VDD, the plurality of data lines DL, the plurality of reference lines RL, and the light shielding layer LS may be configured by a conductive material, such as copper (Cu), aluminum (Al), molybdenum (Mo), nickel (Ni), titanium (Ti), and chrome (Cr), or an alloy thereof, but are not limited thereto.

The plurality of high potential power lines VDD is wiring lines which transmit the high potential power signal to each of the plurality of sub pixels SP. The plurality of high potential power lines VDD may extend between the plurality of sub pixels SP in a column direction and two sub pixels SP which are adjacent to each other in the row direction may share one high potential power line VDD among the plurality of high potential power lines VDD. For example, one high potential power line VDD is disposed at a left side of the red sub pixel SPR to supply a high potential power voltage to the first transistor TR1 of each of the red sub pixel SPR and the white sub pixel SPW. The other high potential power line VDD is disposed at a right side of the green sub pixel SPG to supply a high potential power voltage to the first transistor TR1 of each of the blue sub pixel SPB and the green sub pixel SPG.

The plurality of data lines DL is lines which extend between the plurality of sub pixels SP in a column direction to transmit a data voltage to each of the plurality of sub pixels SP and includes a first data line DL1, a second data line DL2, a third data line DL3, and a fourth data line DL4. The first data line DL1 is disposed between the red sub pixel SPR and the white sub pixel SPW to transmit a data voltage to the second transistor TR2 of the red sub pixel SPR. The second data line DL2 is disposed between the first data line DL1 and the white sub pixel SPW to transmit the data voltage to the second transistor TR2 of the white sub pixel SPW. The third data line DL3 is disposed between the blue sub pixel SPB and the green sub pixel SPG to transmit a data voltage to the second transistor TR2 of the blue sub pixel SPB. The fourth data line DLA is disposed between the third data line DL3 and the green sub pixel SPG to transmit the data voltage to the second transistor TR2 of the green sub pixel SPG.

The plurality of reference lines RL extends between the plurality of sub pixels SP in the column direction to transmit a reference voltage to each of the plurality of sub pixels SP. The plurality of sub pixels SP which forms one pixel may share one reference line RL. For example, one reference line RL is disposed between the white sub pixel SPW and the blue sub pixel SPB to transmit a reference voltage to a third transistor TR3 of each of the red sub pixel SPR, the white sub pixel SPW, the blue sub pixel SPB, and the green sub pixel SPG.

Referring to FIGS. 4 and 5 together, a light shielding layer LS is disposed on the lower buffer layer 116. The light shielding layer LS is disposed so as to overlap the first active layer ACT1 of at least the first transistor TR1 among the plurality of transistors TR1, TR2, and TR3 to block light incident onto the first active layer ACT1. If light is irradiated onto the first active layer ACT1, a leakage current is generated so that the reliability of the first transistor TR1 which is a driving transistor may be degraded. At this time, if the light shielding layer LS configured by an opaque conductive material, such as copper (Cu), aluminum (Al), molybdenum (Mo), nickel (Ni), titanium (Ti), and chrome (Cr), or an alloy thereof, is disposed so as to overlap the first active layer ACT1, light incident from the lower portion of the lower substrate 101 onto the first active layer ACT may be blocked. Accordingly, the reliability of the first transistor TR1 may be improved. However, it is not limited thereto and the light shielding layer LS may also be disposed so as to overlap the second active layer ACT2 of the second transistor TR2 and the third active layer ACT3 of the third transistor TR3.

In the meantime, even though in the drawing, it is illustrated that the light single layer LS is a single layer, the light shielding layer LS may be formed as a plurality of layers. For example, the light shielding layer LS may be formed of a plurality of layers disposed so as to overlap each other with at least one of the lower buffer layer 118, the upper buffer layer 111, the gate insulating layer 112, and the passivation layer 113 therebetween.

The upper buffer layer 111 is disposed on the plurality of high potential power lines VDD, the plurality of data lines DL, the plurality of reference lines RL, and the light shielding layer LS. The upper buffer layer 111 may reduce permeation of moisture or impurities through the lower substrate 101. For example, the upper buffer layer 111 may be configured by a single layer or a plurality of layers of silicon oxide (SiOx) or silicon nitride (SiNx), but is not limited thereto. Further, the upper buffer layer 111 may also be omitted depending on a type of lower substrate 101 or a type of transistor, but is not limited thereto.

In each of the plurality of sub pixels SP, the first transistor TR1, the second transistor TR2, the third transistor TR3, and the storage capacitor SC are disposed on the upper buffer layer 111.

First, the first transistor TR1 includes a first active layer ACT1, a first gate electrode GE1, a first source electrode SE1, and a first drain electrode DE1.

The first active layer ACT1 is disposed on the upper buffer layer 111. The first active layer ACT1 may be formed of a semiconductor material such as an oxide semiconductor, amorphous silicon, or polysilicon, but is not limited thereto. For example, when the first active layer ACT1 is formed of an oxide semiconductor, the first active layer ACT1 is formed by a channel region, a source region, and a drain region and the source region and the drain region may be conductive regions, but are not limited thereto.

The inorganic layer 110 is disposed on the first active layer ACT1. The inorganic layer 110 may include a plurality of layers configured by an inorganic material disposed on the lower substrate 101. For example, the inorganic layer 110 may include an upper buffer layer 111, a gate insulating layer 112, and a passivation layer 113, but is not limited thereto.

An end of the inorganic layer 110 may be disposed at the inside more than the end of the upper substrate 140. For example, the inorganic layer 110 may be disposed so as to expose the end of the outer pattern 102. For example, an end of the inorganic layer 110 may be at the inside more than the end of the outer pattern 102.

The gate insulating layer 112 is disposed on the first active layer ACT1. The gate insulating layer 112 is a layer for electrically insulating the first gate electrode GE1 from the first active layer ACT1 and may be formed of an insulating material. For example, the gate insulating layer 112 may be configured by a single layer or a plurality of layers of silicon oxide (SiOx) or silicon nitride (SiNx), but is not limited thereto.

The first gate electrode GE1 is disposed on the gate insulating layer 112 so as to overlap the first active layer ACT1. The first gate electrode GE1 may be configured by a conductive material such as copper (Cu), aluminum (Al), molybdenum (Mo), nickel (Ni), titanium (Ti), and chrome (Cr), or an alloy thereof, but is not limited thereto.

A first source electrode SE1 and a first drain electrode DE1 which are spaced apart from each other are disposed on the gate insulating layer 112. The first source electrode SE1 and the first drain electrode DE1 may be electrically connected to the first active layer ACT1 through a contact hole formed on the gate insulating layer 112. The first source electrode SE1 and the first drain electrode DE1 may be disposed on the same layer as the first gate electrode GE1 to be formed of the same conductive material, but is not limited thereto. For example, the first source electrode SE1 and the first drain electrode DE1 may be configured by copper (Cu), aluminum (Al), molybdenum (Mo), nickel (Ni), titanium (Ti), chrome (Cr), or an alloy thereof, but are not limited thereto.

The first drain electrode DE1 is electrically connected to the high potential power lines VDD. For example, the first drain electrodes DE1 of the red sub pixel SPR and the white sub pixel SPW may be electrically connected to the high potential power line VDD at the left side of the red sub pixel SPR. The first drain electrodes DE1 of the blue sub pixel SPB and the green sub pixel SPG may be electrically connected to the high potential power line VDD at the right side of the green sub pixel SPG.

At this time, an auxiliary high potential power line VDDa may be further disposed to electrically connect the first drain electrode DE1 with the high potential power line VDD. One end of the auxiliary high potential power line VDDa is electrically connected to the high potential power line VDD and the other end may be electrically connected to the first drain electrode DE1 of each of the plurality of sub pixels SP. For example, when the auxiliary high potential power line VDDa is formed of the same material on the same layer as the first drain electrode DE1, one end of the auxiliary high potential power line VDDa is electrically connected to the high potential power line VDD through a contact hole formed in the gate insulating layer 112 and the upper buffer layer 111. The other end of the auxiliary high potential power line VDDa extends to the first drain electrode DE1 to be integrally formed with the first drain electrode DE1.

At this time, the first drain electrode DE1 of the red sub pixel SPR and the first drain electrode DE1 of the white sub pixel SPW which are electrically connected to the same high potential power lines VDD may be connected to the same auxiliary high potential power line VDDa. The first drain electrode DE1 of the blue sub pixel SPB and the first drain electrode DE1 of the green sub pixel SPG may also be connected to the same auxiliary high potential power line VDDa. However, the first drain electrode DE1 and the high potential power line VDD may also be electrically connected by another method, but it is not limited thereto.

The first source electrode SE1 may be electrically connected to the light shielding layer LS through a contact hole formed on the gate insulating layer 112 and the upper buffer layer 111. Further, a part of the first active layer ACT1 connected to the first source electrode SE1 may be electrically connected to the light shielding layer LS through a contact hole formed on the upper buffer layer 111. If the light shielding layer LS is floated, a threshold voltage of the first transistor TR1 fluctuates to affect the driving of the display device 100. Accordingly, the light shielding layer LS is electrically connected to the first source electrode SE1 to apply a voltage to the light shielding layer LS and it may not affect the driving of the first transistor TR1. However, in the present specification, even though it has been described that both the first active layer ACT1 and the first source electrode SE1 are in contact with the light shielding layer LS, only any one of the first source electrode SE1 and the first active layer ACT1 may also be in direct contact with the light shielding layer LS. It is not limited thereto.

In the meantime, even though in FIG. 5, it is illustrated that the gate insulating layer 112 is formed on the entire lower substrate 101, the gate insulating layer 112 may be patterned so as to overlap only the first gate electrode GE1, the first source electrode SE1, and the first drain electrode DE1, but is not limited thereto.

The second transistor TR2 includes a second active layer ACT2, a second gate electrode GE2, a second source electrode SE2, and a second drain electrode DE2.

The second active layer ACT2 is disposed on the upper buffer layer 111. The second active layer ACT2 may be formed of a semiconductor material such as an oxide semiconductor, amorphous silicon, or polysilicon, but is not limited thereto. For example, when the second active layer ACT2 is formed of an oxide semiconductor, the second active layer ACT2 may be formed by a channel region, a source region, and a drain region and the source region and the drain region may be conductive regions, but are not limited thereto.

The second source electrode SE2 is disposed on the upper buffer layer 111. The second source electrode SE2 may be integrally formed with the second active layer ACT2 to be electrically connected to each other. For example, the semiconductor material is formed on the upper buffer layer 111 and a part of the semiconductor material is conducted to form the second source electrode SE2. Therefore, a part of the semiconductor material which is not conducted may become a second active layer ACT2 and a conducted part may serve as a second source electrode SE2. However, the second active layer ACT2 and the second source electrode SE2 may be separately formed, but are not limited thereto.

The second source electrode SE2 is electrically connected to the first gate electrode GE1 of the first transistor TR1. The first gate electrode GE1 may be electrically connected to the second source electrode SE2 through a contact hole formed on the gate insulating layer 112. Accordingly, the first transistor TR1 may be turned on or turned off by a signal from the second transistor TR2.

The gate insulating layer 112 is disposed on the second active layer ACT2 and the second source electrode SE2 and the second drain electrode DE2 and the second gate electrode GE2 are disposed on the gate insulating layer 112.

The second gate electrode GE2 is disposed on the gate insulating layer 112 so as to overlap the second active layer ACT2. The second gate electrode GE2 may be electrically connected to the gate line GL and the second transistor TR2 may be turned on or turned off based on the gate voltage transmitted to the second gate electrode GE2. The second gate electrode GE2 may be configured by a conductive material such as copper (Cu), aluminum (Al), molybdenum (Mo), nickel (Ni), titanium (Ti), and chrome (Cr), or an alloy thereof, but is not limited thereto.

In the meantime, the second gate electrode GE2 may extend from the gate line GL. That is, the second gate electrode GE2 may be integrally formed with the gate line GL and the second gate electrode GE2 and the gate line GL may be formed of the same conductive material. For example, the gate line GL may be configured by copper (Cu), aluminum (Al), molybdenum (Mo), nickel (Ni), titanium (Ti), chrome (Cr), or an alloy thereof, but is not limited thereto.

The gate line GL is a wiring line which transmits the gate voltage to each of the plurality of sub pixels SP and intersects the circuit area of the plurality of sub pixels SP to extend in the row direction. The gate line GL extends in the row direction to intersect the plurality of high potential power lines VDD, the plurality of data lines DL, and the plurality of reference lines RL extending in the column direction.

The second drain electrode DE2 is disposed on the gate insulating layer 112. The second drain electrode DE2 is electrically connected to the second active layer ACT2 through a contact hole formed in the gate insulating layer 112 and may be electrically connected to one of the plurality of data lines DL through a contact hole formed in the gate insulating layer 112 and the upper buffer layer 111, simultaneously. For example, the second drain electrode DE2 of the red sub pixel SPR is electrically connected to the first data line DL1 and the second drain electrode DE2 of the white sub pixel SPW may be electrically connected to the second data line DL2. For example, the second drain electrode DE2 of the blue sub pixel SPB is electrically connected to the third data line DL3 and the second drain electrode DE2 of the green sub pixel SPG may be electrically connected to the fourth data line DL4. The second drain electrode DE2 may be configured by a conductive material, such as copper (Cu), aluminum (Al), molybdenum (Mo), nickel (Ni), titanium (Ti), and chrome (Cr), or an alloy thereof, but is not limited thereto.

The third transistor TR3 includes a third active layer ACT3, a third gate electrode GE3, a third source electrode SE3, and a third drain electrode DE3.

The third active layer ACT3 is disposed on the upper buffer layer 111. The third active layer ACT3 may be formed of a semiconductor material, such as an oxide semiconductor, amorphous silicon, or polysilicon, but is not limited thereto. For example, when the third active layer ACT3 is formed of an oxide semiconductor, the third active layer ACT3 is formed by a channel region, a source region, and a drain region and the source region and the drain region may be conductive regions, but are not limited thereto.

The gate insulating layer 112 is disposed on the third active layer ACT3 and the third gate electrode GE3, the third source electrode SE3, and the third drain electrode DE3 are disposed on the gate insulating layer 112.

The third gate electrode GE3 is disposed on the gate insulating layer 112 so as to overlap the third active layer ACT3. The third gate electrode GE3 may be electrically connected to the sensing line SL and the third transistor TR3 may be turned on or turned off based on the sensing voltage transmitted to the third transistor TR3. The third gate electrode GE3 may be configured by a conductive material such as copper (Cu), aluminum (Al), molybdenum (Mo), nickel (Ni), titanium (Ti), and chrome (Cr), or an alloy thereof, but is not limited thereto.

In the meantime, the third gate electrode GE3 may extend from the sensing line SL. That is, the third gate electrode GE3 is integrally formed with the sensing line SL and the third gate electrode GE3 and the sensing line SL may be formed of the same conductive material. For example, the sensing line SL may be configured by copper (Cu), aluminum (Al), molybdenum (Mo), nickel (Ni), titanium (Ti), chrome (Cr), or an alloy thereof, but is not limited thereto.

The sensing line SL transmits a sensing voltage to each of the plurality of sub pixels SP and extends between the plurality of sub pixels SP in a row direction. For example, the sensing line SL extends at a boundary between the plurality of sub pixels SP in the row direction to intersect the plurality of high potential power lines VDD, the plurality of data lines DL, and the plurality of reference lines RL extending in the column direction.

The third source electrode SE3 may be electrically connected to the third active layer ACT3 through a contact hole formed on the gate insulating layer 112. The third source electrode SE3 may be configured by a conductive material, such as copper (Cu), aluminum (Al), molybdenum (Mo), nickel (Ni), titanium (Ti), and chrome (Cr), or an alloy thereof, but is not limited thereto.

Further, a part of the third active layer ACT3 which is in contact with the third source electrode SE3 may be electrically connected to the light shielding layer LS through a contact hole formed in the upper buffer layer 111. That is, the third source electrode SE3 may be electrically connected to the light shielding layer LS with the third active layer ACT3 therebetween. Therefore, the third source electrode SE3 and the first source electrode SE1 may be electrically connected to each other by means of the light shielding layer LS.

The third drain electrode DE3 may be electrically connected to the third active layer ACT3 through a contact hole formed on the gate insulating layer 112. The third drain electrode DE3 may be configured by a conductive material such as copper (Cu), aluminum (Al), molybdenum (Mo), nickel (Ni), titanium (Ti), and chrome (Cr), or an alloy thereof, but is not limited thereto.

The third drain electrode DE3 may be electrically connected to the reference line RL. For example, the third drain electrodes DE3 of the red sub pixel SPR, the white sub pixel SPW, the blue sub pixel SPB, and the green sub pixel SPG may be electrically connected to the same reference line RL. That is, the plurality of sub pixels SP which forms one pixel may share one reference line RL.

At this time, an auxiliary reference line RLa may be disposed to transmit the reference line RL extending in the column direction to the plurality of sub pixels SP which is disposed in parallel along the row direction. The auxiliary reference line Rla extends in the row direction to electrically connect the reference line RL and the third drain electrode DE3 of each of the plurality of sub pixels SP. One end of the auxiliary reference line Rla is electrically connected to the reference line RL through a contact hole formed in the upper buffer layer 111 and the gate insulating layer 112. The other end of the auxiliary reference line Rla may be electrically connected to the third drain electrode DE3 of each of the plurality of sub pixels SP. In this case, the auxiliary reference line Rla may be integrally formed with the third drain electrode DE3 of each of the plurality of sub pixels SP and a reference voltage from the reference line RL may be transmitted to the third drain electrode DE3 by means of the auxiliary reference line Rla. However, the auxiliary reference line Rla may be separately formed from the third drain electrode DE3, but is not limited thereto.

The storage capacitor SC is disposed in the circuit area of the plurality of sub pixels SP. The storage capacitor SC may store a voltage between the first gate electrode GE1 and the first source electrode SE1 of the first transistor TR1 to allow the light emitting diode OLED to continuously maintain a constant state for one frame. The storage capacitor SC includes a first capacitor electrode SC1 and a second capacitor electrode SC2.

In each of the plurality of sub pixels SP, the first capacitor electrode SC1 is disposed between the lower buffer layer 116 and the upper buffer layer 111. The first capacitor electrode SC1 may be disposed to be the closest to the lower substrate 101 among the conductive components disposed on the lower substrate 101. The first capacitor electrode SC1 may be integrally formed with the light shielding layer LS and may be electrically connected to the first source electrode SE1 by means of the light shielding layer LS.

The upper buffer layer 111 is disposed on the first capacitor electrode SC1 and the second capacitor electrode SC2 is disposed on the upper buffer layer 111. The second capacitor electrode SC2 may be disposed so as to overlap the first capacitor electrode SC1. The second capacitor electrode SC2 is integrally formed with the second source electrode SE2 to be electrically connected to the second source electrode SE2 and the first gate electrode GE1. For example, the semiconductor material is formed on the upper buffer layer 111 and a part of the semiconductor material is conducted to form the second source electrode SE2 and the second capacitor electrode SC2. Accordingly, a part of the semiconductor material which is not conducted functions as a second active layer ACT2 and the conducted part functions as a second source electrode SE2 and the second capacitor electrode SC2. As described above, the first gate electrode GE1 is electrically connected to the second source electrode SE2 through the contact hole formed in the gate insulating layer 112. Accordingly, the second capacitor electrode SC2 is integrally formed with the second source electrode SE2 to be electrically connected to the second source electrode SE2 and the first gate electrode GE1.

In summary, the first capacitor electrode SC1 of the storage capacitor SC is integrally formed with the light shielding layer LS to be electrically connected to the light shielding layer LS, the first source electrode SE1, and the third source electrode SE3. Accordingly, the second capacitor electrode SC2 is integrally formed with the second source electrode SE2 and the active layer ACT2 to be electrically connected to the second source electrode SE2 and the first gate electrode GE1. Accordingly, the first capacitor electrode SC1 and the second capacitor electrode SC2 which overlap with the upper buffer layer 111 therebetween constantly maintain the voltages of the first gate electrode GE1 and the first source electrode SE1 of the first transistor TR1 to maintain the constant state of the light emitting diode OLED.

The passivation layer 113 is disposed on the first transistor TR1, the second transistor TR2, the third transistor TR3, and the storage capacitor SC. The passivation layer 113 is an insulating layer for protecting components below the passivation layer 113. For example, the passivation layer 113 may be configured by a single layer or a plurality of layers of silicon oxide (SiOx) or silicon nitride (SiNx), but is not limited thereto. Further, the passivation layer 113 may also be omitted depending on the exemplary embodiment.

A plurality of color filters CF is disposed in the emission area of each of the plurality of sub pixels SP on the passivation layer 113. As described above, the display device 100 according to the exemplary embodiment of the present disclosure is a bottom emission type in which light emitted from the light emitting diode OLED is directed to the lower portion of the light emitting diode OLED and the lower substrate 101. Therefore, the plurality of color filters CF may be disposed below the light emitting diode OLED. Light emitted from the light emitting diode OLED passes through the plurality of color filters CF and may be implemented as various colors of light.

The plurality of color filters CF includes a red color filter CFR, a blue color filter CFB, and a green color filter CFG. The red color filter CFR may be disposed in an emission area of a red sub pixel SPR of the plurality of sub pixels SP, the blue color filter CFB may be disposed in an emission area of the blue sub pixel SPB, and the green color filter CFG may be disposed in an emission area of the green sub pixel SPG.

The planarization layer 114 is disposed on the passivation layer 113 and the plurality of color filters CF.

The planarization layer 114 is an insulating layer which planarizes an upper portion of the lower substrate 101 on which the first transistor TR1, the second transistor TR2, the third transistor TR3, the storage capacitor SC, the plurality of high potential power lines VDD, the plurality of data lines DL, the plurality of reference lines RL, the plurality of gate lines GL, and the plurality of sensing lines SL are disposed. The planarization layer 114 may be formed of an organic material, for example, may be configured by an acryl based single layer or multiple layers, but is not limited thereto.

The light emitting diode OLED is disposed in an emission rea of each of the plurality of sub pixels SP. The light emitting diode OLED is disposed on the planarization layer 114 in each of the plurality of sub pixels SP. The light emitting diode OLED includes an anode AN, an emission layer EL, and a cathode CA.

The anode AN is disposed on the planarization layer 114 in the emission area. The anode AN supplies holes to the emission layer EL so that the anode may be formed of a conductive material having a high work function. For example, the anode AN may be formed of a transparent conductive material such as indium tin oxide (ITO) and indium zinc oxide (IZO), but is not limited thereto.

In the meantime, the anode AN may extend toward the circuit area. A part of the anode AN may extend toward the first source electrode SE1 of the circuit area from the emission area and may be electrically connected to the first source electrode SE1 through a contact hole formed in the planarization layer 114 and the passivation layer 113. Accordingly, the anode AN of the light emitting diode OLED extends to the circuit area to be electrically connected to the first source electrode SE1 of the first transistor TR1 and the second capacitor electrode SC2 of the storage capacitor SC.

In the emission area and the circuit area, the emission layer EL is disposed on the anode AN. The emission layer EL may be formed as one layer over the plurality of sub pixels SP. That is, the emission layers EL of the plurality of sub pixels SP are connected to each other to be integrally formed. The emission layer EL may also be configured by one emission layer or may have a structure in which a plurality of emission layers which emits different color light is laminated. The emission layer EL may further include an organic layer, such as a hole injection layer, a hole transport layer, an electron transport layer, and an electron injection layer.

The cathode CA is disposed on the emission layer EL in the emission area and the circuit area. The cathode CA supplies electrons to the emission layer EL so that the cathode may be formed of a conductive material having a low work function. The cathode CA may be formed as one layer over the plurality of sub pixels SP. That is, the cathodes CA of the plurality of sub pixels SP are connected to be integrally formed. For example, the cathode CA may be formed of a transparent conductive material such as indium tin oxide (ITO) and indium zinc oxide (IZO) or ytterbium (Yb) alloy and may also further include a metal doping layer, but is not limited thereto. Even though it is not illustrated in FIGS. 4 and 6A, the cathode CA of the light emitting diode OLED is electrically connected to the low potential power line VSS to be supplied with a low potential power voltage.

The bank 115 is disposed between the anode AN and the emission layer EL. The bank 115 is disposed to overlap the active area AA and cover the edge of the anode AN. The bank 115 is disposed at the boundary between the sub pixels SP which are adjacent to each other to reduce the color mixture of light emitted from the light emitting diode OLED of each of the plurality of sub pixels SP. The bank 115 may be formed of an insulating material such as, polyimide, acryl, or benzocyclobutene (BCB) resin, but it is not limited thereto.

The outer pattern 102 disposed in the non-active area NA will be described in detail with reference to FIGS. 6A and 6B.

Referring to FIG. 6B, in the non-active area NA, the polarizer 150, the lower substrate 101, the outer pattern 102, the lower buffer layer 116, the gate driver GD, the low potential power line VSS, the inorganic layer 110, the planarization layer 114, the bank 115, the cathode CA, the adhesive layer 130, and the upper substrate 140 are sequentially disposed. The seal member 141 is disposed on a side surface of the upper substrate 140. The non-active area NA illustrated in FIG. 6B is a non-active area NA of a side portion excluding one side in which the flexible film 160 is disposed on the lower substrate 101.

In order to describe the manufacturing process, referring to FIG. 6A, the temporary substrate SUB is disposed below the lower substrate 101 with a larger area than the lower substrate 101 to cover a bottom surface of the lower substrate 101 and the outer pattern 102. The temporary substrate SUB is a substrate which supports the lower substrate 101 and the outer pattern 102 and components disposed on the lower substrate 101 and the outer pattern 102 during the manufacturing process of the display device 100. The temporary substrate SUB may be formed of a material having a rigidity. For example, the temporary substrate SUB may be formed of glass, but is not limited thereto.

The outer pattern 102 is disposed on the temporary substrate SUB. The outer pattern 102 may be disposed so as to correspond to an outer peripheral portion of the temporary substrate SUB. Therefore, the outer pattern 102 may be not disposed in a center portion of the temporary substrate SUB, but may be disposed with a closed curve so as to correspond to the outer peripheral portion.

Further, a thickness of the outer pattern 102 may be reduced as it closes to the center portion of the temporary substrate SUB. For example, after forming a layer formed of polyimide PI on the temporary substrate SUB, in the outer pattern 102, an area disposed to be close to the center portion of the temporary substrate SUB may be removed by a process, such as dry etch. Accordingly, the outer pattern 102 is disposed with a constant thickness at the edge of the temporary substrate SUB and may have a thickness which is reduced as it is closer to the center portion of the temporary substrate SUB. The outer pattern 102 may be disposed to have a thickness of 1700 Å to 5500 Å in an area overlapping the edge of the temporary substrate SUB and the thickness of the outer pattern 102 may be adjusted by controlling a viscosity of a material which configures the outer pattern 102.

An auxiliary layer AL is disposed on the temporary substrate SUB. The auxiliary layer AL is disposed between the sacrificial layer SL and the temporary substrate SUB to improve the adhesiveness of the sacrificial layer SL and the temporary substrate SUB. For example, the auxiliary layer AL may be configured by a material, such as silicon nitride (SiNx).

The sacrificial layer SL is disposed on the outer pattern 102 and the temporary substrate SUB. Specifically, the sacrificial layer SL is disposed on the auxiliary layer AL. The sacrificial layer SL is a layer formed to easily separate the temporary substrate SUB and the lower substrate 101 from each other. Therefore, the sacrificial layer SL is disposed with the same area as the lower substrate 101 and may be formed with a smaller area than the temporary substrate SUB. At this time, the sacrificial layer SL may be disposed so as to overlap a part of the outer pattern 102. Laser is irradiated onto the sacrificial layer SL from the lower portion of the temporary substrate SUB to dehydrogenate the sacrificial layer SL and separate the temporary substrate SUB and the sacrificial layer SL from the lower substrate 101. For example, the sacrificial layer SL may use hydrogenated amorphous silicon or amorphous silicon which is hydrogenated and doped with impurities.

The lower substrate 101 is disposed on the sacrificial layer SL. The lower substrate 101 may be disposed with the same area so as to fully overlap the sacrificial layer SL. Therefore, the lower substrate 101 is disposed in the center portion of the temporary substrate SB and may be disposed so as to overlap a part of the outer pattern 102.

The lower buffer layer 116 is disposed on the lower substrate 101. The lower buffer layer 116 may be disposed so as to overlap the lower substrate 101 and the outer pattern 102. The lower buffer layer 116 is formed of an inorganic material so that as illustrated in FIG. 6A, the lower buffer layer may be formed along a shape of the top surface of a configuration disposed therebelow, but is not limited thereto.

The gate driver GD may be disposed on the outer pattern 102 and the lower buffer layer 116. The gate driver GD overlaps the outer pattern 102 and may not overlap the lower substrate 101. The gate driver GD may generate and output a gate voltage and a sensing voltage as described above. Even though in FIG. 6A, the gate driver GD is illustrated as a block, the gate driver GD may be actually configured by a plurality of transistors and a capacitor. As illustrated in FIG. 6A, the gate driver GD may be connected to a gate line GL disposed in the active area AA through a gate link line GLL and transmit the gate voltage to the gate line GL through the gate link line GLL.

A low potential power line VSS is disposed on the lower buffer layer 116. The low potential power line VSS may be disposed between the gate driver GD and the active area AA in the non-active area NA. The low potential power line VSS may be disposed at the inside more than the end of the lower substrate 101 to overlap the lower substrate 101.

The inorganic layer 110 and the gate link line GLL are disposed on the lower buffer layer 116 and the low potential power line VSS. The inorganic layer 110 and the gate link line GLL are disposed so as to overlap the lower substrate 101 and the outer pattern 102 in the non-active area NA and may be connected to the gate driver GD. Therefore, the inorganic layer 110 and the gate link line GLL may have top surfaces curved along top surfaces of the outer pattern 102, the lower substrate 101, and the lower buffer layer 116.

The planarization layer 114 is disposed on the inorganic layer 110. An end of the planarization layer 114 may be located so as to cover the end of the inorganic layer 110 in the non-active area NA. At this time, the planarization layer 114 may overlap the lower substrate 101 and may be disposed so as to overlap a part of the outer pattern 102 disposed at the outside of the lower substrate 101.

The planarization layer 114 may relieve a step generated in the inorganic layer 110 and the lower buffer layer 116 disposed therebelow. That is, the planarization layer 114 may have a flat top surface so as to planarize the bank 115 disposed thereabove.

The bank 115 is disposed on the temporary substrate SUB, the lower substrate 101, the inorganic layer 110, and the planarization layer 114. The bank 115 may be disposed so as to overlap the planarization layer 114. Therefore, the bank 115 may overlap the lower substrate 101 and may be disposed so as to overlap a part of the outer pattern 102.

The cathode CA, the adhesive layer 130, and the upper substrate 140 may be disposed on the bank 115. The upper substrate 140 may be disposed to have a larger area than the lower substrate 101 so as to cover the entire lower substrate 101 so that the end of the upper substrate 140 may be disposed on the outer pattern 102.

The seal member 141 disposed to enclose the side surface of the upper substrate 140 may be disposed. The seal member 141 is disposed at the edge of the display device 100 so as to overlap the outer pattern 102, but may be disposed so as not to overlap the lower substrate 101. The seal member 141 may be formed of an organic material, for example, may be configured by an acryl based single layer or multiple layers.

Next, the lower substrate 101 and the temporary substrate SUB may be separated from each other by means of the LLO process.

During the LLO process, the lower substrate 101 may be separated from the temporary substrate SUB. The sacrificial layer SL may use hydrogenated amorphous silicon or hydrogenated amorphous silicon doped with impurities. When the laser is irradiated toward the temporary substrate SUB and the sacrificial layer SL from the lower portion of the temporary substrate SUB, the hydrogen of the sacrificial layer SL is dehydrogenated and the sacrificial layer SL and the temporary substrate SUB may be separated from the lower substrate 101.

During the LLO process, the temporary substrate SUB disposed at the outside of the lower substrate 101 and the outer pattern 102 may be separated. If in an area at the outside of the sacrificial layer, a layer which is formed of a material having a low laser absorptivity is disposed, laser irradiated during the LLO passes through the corresponding layer so that it may be difficult to separate the temporary substrate due to the adhesiveness with the temporary substrate. Even though the corresponding layer is separated from the temporary substrate, crack is generated so that the inorganic layer or the lower substrate may also be cracked. The outer pattern 102 is formed of polyimide which is a material having a higher laser absorptivity to absorb the laser. Therefore, a part of the temporary substrate SUB which is in contact with the outer pattern 102 may be easily separated during the LLO process.

When the above-mentioned LLO process is completed, as illustrated in FIG. 6B, the lower substrate 101 and the outer pattern 102 remain. As described above, during the LLO process, a part of the sacrificial layer SL and the auxiliary layer AL which overlaps the outer pattern 102 remains to be disposed on the outer pattern 102. However, in a part which does not overlap the outer pattern 102, the sacrificial layer SL and the auxiliary layer AL disposed below the lower substrate 101 may be removed together during a process of removing the temporary substrate SUB.

Therefore, the sacrificial layer SL and the auxiliary layer AL may not be removed from an area which overlaps the outer pattern 102 and the lower substrate 101. For example, when the laser is irradiated onto the outer pattern 102, the outer pattern 102 absorbs most of the energy of the laser so that the laser which reaches the sacrificial layer SL may be extremely small. Therefore, the sacrificial layer SL disposed on the outer pattern 102 is not decomposed during the LLO process so that the sacrificial layer SL and the auxiliary layer AL are not removed, but may be disposed on the outer pattern 102.

Next, the polarizer 150 is disposed below the outer pattern 102 and the lower substrate 101.

Referring to FIG. 6B, the adhesive member AD may be disposed on bottom surfaces of the outer pattern 102 and the lower substrate 101. Therefore, the adhesive member AD may protrude to an area from which the sacrificial layer SL is removed.

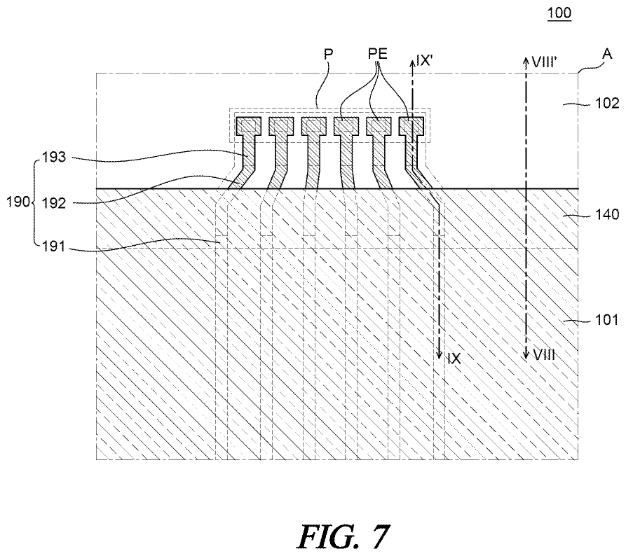

Hereinafter, the pad area in which the flexible film 160 is disposed will be described with reference to FIGS. 7 to 9B.

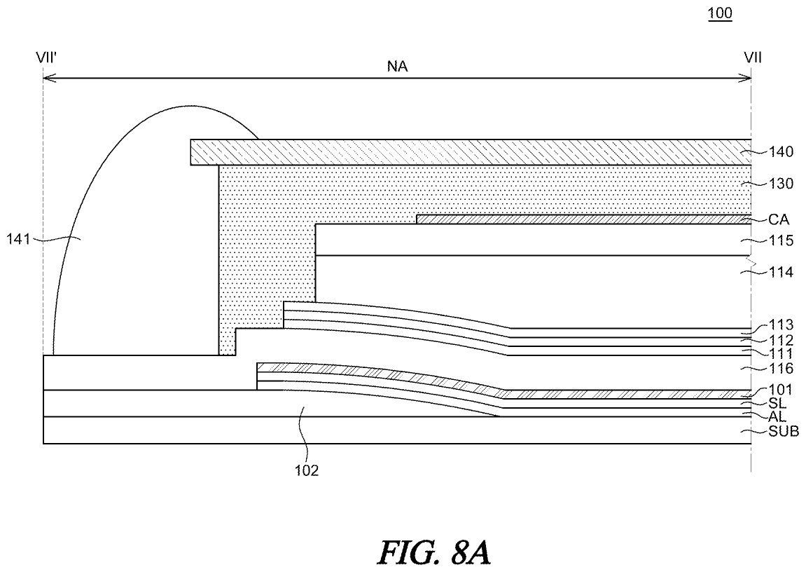

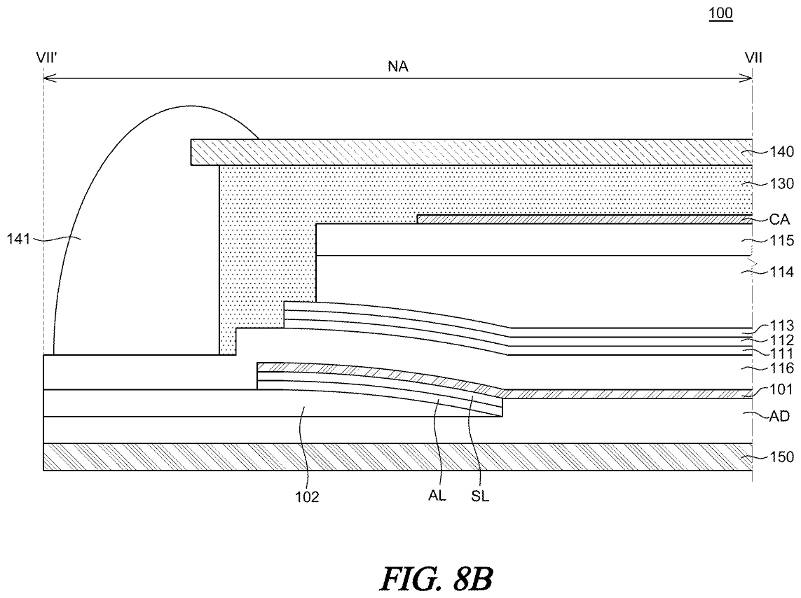

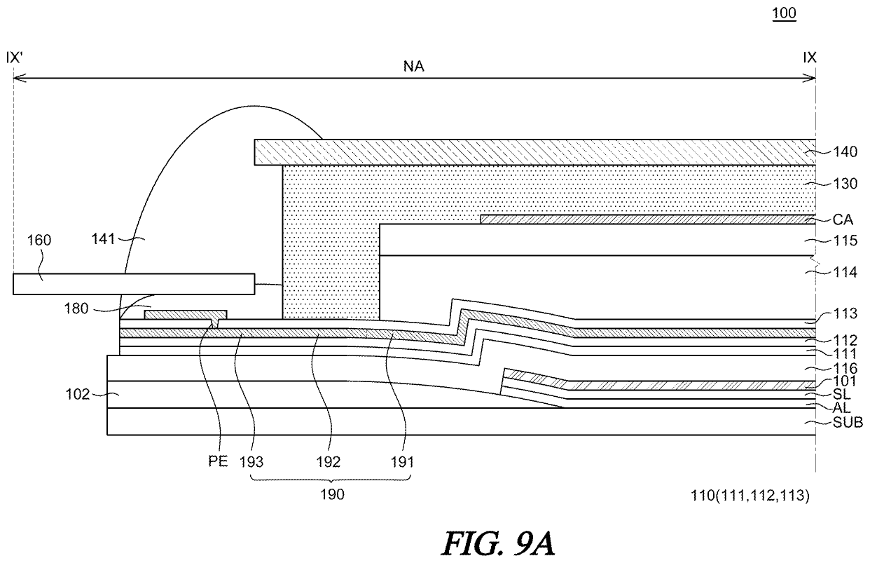

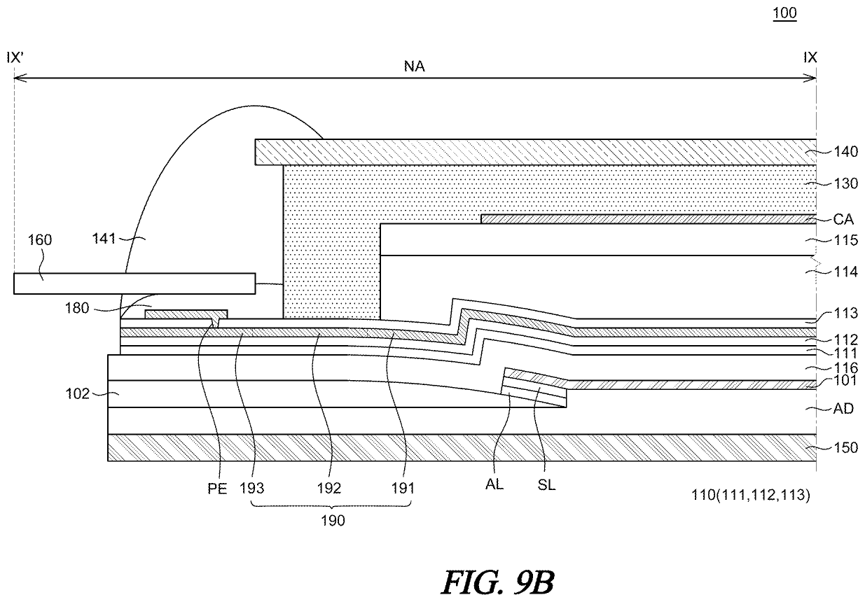

FIG. 7 is an enlarged view of an area A of FIG. 1. In FIG. 7, for the convenience of illustration, only a part of the lower substrate 101, the pad unit P, a plurality of link lines 190, and the upper substrate 140 is illustrated. FIG. 7 is a plan view of a pad unit P corresponding to one flexible film 160. FIG. 8 is a cross-sectional view taken along the line VIII′-VIII of FIG. 7, and FIG. 9 is a cross-sectional view taken along IX′-IX of FIG. 7.

Referring to FIGS. 7 to 8B, in the non-active area NA between the pad units P, the polarizer 150, the lower substrate 101, the outer pattern 102, the lower buffer layer 116, the inorganic layer 110, the planarization layer 114, the bank 115, the cathode CA, the adhesive layer 130, and the upper substrate 140 are sequentially disposed. The seal member 141 is disposed on a side surface of the upper substrate 140.

First, in order to describe the manufacturing process, referring to FIG. 8A, the outer pattern 102 is disposed at the outer peripheral portion of the temporary substrate SUB.

The outer pattern 102 is disposed with a constant thickness of 1700 Å to 5500 Å at the edge of the temporary substrate SUB and may have a thickness which is reduced as it is closer to the center portion of the temporary substrate SUB.

The sacrificial layer SL and the auxiliary layer AL are disposed on the temporary substrate SUB. The sacrificial layer SL and the auxiliary layer AL may be disposed so as to overlap a part of the outer pattern 102.

The lower substrate 101 is disposed on the sacrificial layer SL. The lower substrate 101 may be disposed with the same area as the sacrificial layer SL so as to completely overlap the sacrificial layer SL.

The lower buffer layer 116 is disposed on the lower substrate 101. The lower buffer layer 116 may be disposed so as to overlap the lower substrate 101 and the outer pattern 102.

The inorganic layer 110 is disposed on the lower buffer layer 116. The inorganic layer 110 may have a top surface curved along top surfaces of the outer pattern 102, the lower substrate 101, and the lower buffer layer 116.

The planarization layer 114, the bank 115, the cathode CA, the adhesive layer 130, and the upper substrate 140 may be disposed on the inorganic layer 110. The upper substrate 140 may be disposed to have a larger area than the lower substrate 110 so as to cover the entire lower substrate 101 so that the end of the upper substrate 140 may be disposed on the outer pattern 102.

The seal member 141 disposed to enclose the side surface of the upper substrate 140 may be disposed. The seal member 141 is disposed at the edge of the display device 100 so as to overlap the outer pattern 102, but may be disposed so as not to overlap the lower substrate 101.

Next, during the LLO process, the lower substrate 101 and the outer pattern 102 disposed at the outside of the lower substrate 101 may be separated from the temporary substrate SUB.

When the above-described LLO process is completed, as illustrated in FIG. 8B, the lower substrate 101 and the outer pattern 102 remain.

The sacrificial layer SL and the auxiliary layer AL may be disposed on the outer pattern 102 without being removed from an area which overlaps the outer pattern 102 and the lower substrate 101.

Next, the polarizer 150 is disposed below the outer pattern 102 and the lower substrate 101.

Referring to FIG. 8B, the adhesive member AD may be disposed on bottom surfaces of the outer pattern 102 and the lower substrate 101. Therefore, the adhesive member AD may protrude to an area from which the sacrificial layer SL is removed.

Next, referring to FIGS. 7, 9A, and 9B, in the non-active area NA, the polarizer 150, the lower substrate 101, the outer pattern 102, the lower buffer layer 116, the pad unit P, the pad electrode PE, the plurality of link lines 190, the inorganic layer 110, the planarization layer 114, the bank 115, the cathode CA, the adhesive layer 130, and the upper substrate 140 are sequentially disposed. The seal member 141 is disposed on a side surface of the upper substrate 140. The non-active area NA illustrated in FIGS. 9A and 9B is a cross-sectional view of an area in which the link line 190 is disposed on the lower substrate 101.

First, in order to describe the manufacturing process, referring to FIG. 9A, the outer pattern 102 is disposed so as to correspond to the outer peripheral portion of the temporary substrate SUB.

The outer pattern 102 is disposed with a constant thickness of 1700 Å to 5500 Å at the edge of the temporary substrate SUB and may have a thickness which is reduced as it is closer to the center portion of the temporary substrate SUB.

The sacrificial layer SL and the auxiliary layer AL are disposed on the temporary substrate SUB. The sacrificial layer SL and the auxiliary layer AL may be disposed so as to overlap a part of the outer pattern 102.

The lower substrate 101 is disposed on the sacrificial layer SL. The lower substrate 101 may be disposed with the same area as the sacrificial layer SL so as to completely overlap the sacrificial layer SL.

The lower buffer layer 116 is disposed on the lower substrate 101. The lower buffer layer 116 may be disposed so as to overlap the lower substrate 101 and the outer pattern 102.

The link line 190 is disposed on the lower buffer layer 116.

The plurality of link lines 190 may be connected to a plurality of signal lines, such as a gate link line GLL, a data line DL, a high potential power line VDD, a sensing line SL, and a reference line RL, connected to the plurality of sub pixels SP. Therefore, the plurality of link lines 190 may transmit a signal applied from the flexible film 160 to the plurality of signal lines.

The plurality of link lines 190 may include a first line pattern 191, a second line pattern 192, and a third line pattern 193.

First, the first line pattern 191 may be connected to the plurality of signal lines disposed on the lower substrate 101. That is, the first line pattern 191 is disposed to be more adjacent to the active area AA than the second line pattern 192 and the third line pattern 193 and may also be directly connected to the plurality of signal lines.

The third line pattern 193 may be connected to the pad electrode PE. Therefore, the third line pattern 193 may be disposed to be adjacent to the outer peripheral portion of the lower substrate 101 than the first line pattern 191 and the second line pattern 192.

At this time, the third line pattern 193 may be disposed at the same angle as the first line pattern 191 on the plane. For example, the third line pattern 193 may be disposed in a straight line on the plane.

The second line pattern 192 may be disposed between the first line pattern 191 and the third line pattern 193 so as to electrically connect the first line pattern 191 and the third line pattern 193. The second line pattern 192 may be disposed to be bent at an angle different from those of the first line pattern 191 and the third line pattern 193. For example, the second line pattern 192 may be diagonally disposed between the first line pattern and the third line pattern 193.

The second line pattern 192 may overlap an end of the upper substrate 140. That is, as illustrated in FIGS. 7, 9A, and 9B, the first line pattern 191 is disposed so as to overlap the lower substrate 101 and may overlap a part of the outer pattern 102 disposed at the outside of the lower substrate 101. The third line pattern 193 is disposed at the outside of the upper substrate 140 so as to overlap the outer pattern 102 and the second line pattern 192 may be disposed in an area which overlaps the end of the upper substrate 140. Therefore, the second line pattern 192 may simultaneously overlap the upper substrate 140 and the outer pattern 102.

The inorganic layer 110 is disposed on the lower buffer layer 116 and the plurality of link lines 190. The inorganic layer 110 may have a top surface curved along top surfaces of the outer pattern 102, the lower substrate 101, and the lower buffer layer 116.

The planarization layer 114, the bank 115, the cathode CA, the adhesive layer 130, and the upper substrate 140 may be disposed on the inorganic layer 110. The upper substrate 140 may be disposed to have a larger area than the lower substrate 101 so as to cover the entire lower substrate 101 so that the end of the upper substrate 140 may be disposed on the outer pattern 102.

In the non-active area NA in which the flexible film 160 is disposed, the plurality of pad units P is disposed on the outer pattern 102. The plurality of pad units P includes a plurality of pad electrodes PE. The plurality of pad electrodes PE is electrodes which electrically connect the plurality of link lines 190 and the plurality of flexible films 160. Therefore, the plurality of pad electrodes PE may transmit signals from the printed circuit board 170 and the plurality of flexible films 160 to the plurality of sub pixels SP of the active area AA.

The plurality of pad units P may be disposed so as to overlap the outer pattern 102 at the outside more than the end of the lower substrate 101. Further, the pad unit P may be disposed on the lower substrate 101 having a uniform thickness to have a flat top surface.

The plurality of flexible films 160 is disposed on the plurality of pads units P. One ends of the plurality of flexible films 160 may be electrically connected to the plurality of pad electrodes PE of the plurality of pad units P. At this time, flexible film 160 is disposed at the outside more than the end of the lower substrate 101 to overlap the outer pattern 102.

The plurality of flexible films 160 and the plurality of pad units P may be electrically connected to each other by means of a conductive adhesive member 180. The conductive adhesive member 180 may be a conductive adhesive layer including conductive particles and for example, the conductive adhesive member 180 may be an anisotropic conductive film (ACF), but is not limited thereto.

The seal member 141 disposed to enclose the side surface of the upper substrate 140 may be disposed. The seal member 141 is disposed to cover one end of the flexible film 160 disposed on the top surface of the lower substrate 101. At this time, the seal member 141 may be disposed so as to overlap the outer pattern 102 and the seal member 141 may be disposed at the outside more than the end of the lower substrate 101. The seal member 141 may be formed of an organic material, for example, may be configured by an acryl based single layer or multiple layers.

Next, through the LLO process, the lower substrate 101 and the outer pattern 102 disposed at the outside of the lower substrate 101 may be separated from the temporary substrate SUB.

When the above-described LLO process is completed, as illustrated in FIG. 9B, the lower substrate 101 and the outer pattern 102 remain.

The sacrificial layer SL and the auxiliary layer AL may be disposed on the outer pattern 102 without being removed from an area which overlaps the outer pattern 102 and the lower substrate 101.

Next, the polarizer 150 is disposed below the outer pattern 102 and the lower substrate 101.

Referring to FIG. 9B, the adhesive member AD may be disposed on bottom surfaces of the outer pattern 102 and the lower substrate 101. Therefore, the adhesive member AD may protrude to an area from which the sacrificial layer SL is removed.

In the display device 100 according to the exemplary embodiment of the present disclosure, the lower substrate 101 is formed of any one of a transparent conducting oxide and an oxide semiconductor to reduce a thickness of the display device 100. In the related art, the plastic substrate has been mainly used as the substrate of the display device. However, the plastic substrate is formed by coating and curing a substrate material at a high temperature so that there are problems in that it takes a long time and it is difficult to form the thickness to be lower than a predetermined level. In contrast, the transparent conducting oxide and the oxide semiconductor may be formed to have a very thin thickness by the deposition process such as sputtering. Therefore, in the display device 100 according to the exemplary embodiment of the present disclosure, the lower substrate 101 which supports various components of the display device 100 is configured by a transparent conducting oxide layer or the oxide semiconductor layer to reduce a thickness of the display device 100 and implement a slim design.

Further, in the display device 100 according to the exemplary embodiment of the present disclosure, the lower substrate 101 is formed of a transparent conducting oxide or an oxide semiconductor to improve the flexibility of the display device 100 and reduce the stress generated when the display device 100 is deformed. Specifically, when the lower substrate 101 is configured by the transparent conducting oxide layer or the oxide semiconductor, the lower substrate 101 may be formed as a very thin film. In this case, the lower substrate 101 may also be referred to as a first transparent thin film layer. Accordingly, the display device 100 including the lower substrate 101 may have a high flexibility and the display device 100 may be easily bent or rolled. Therefore, in the display device 100 according to the exemplary embodiment of the present disclosure, the lower substrate 101 is formed by any one of the transparent conducting oxide layer and the oxide semiconductor to improve the flexibility of the display device 100. Accordingly, the stress generated when the display device 100 is deformed may also be relieved so that the crack generated in the display device 100 may be reduced.

Further, in the display device 100 according to the exemplary embodiment of the present disclosure, the lower substrate 101 is formed of any one of a transparent conducting oxide layer and an oxide semiconductor layer to reduce the possibility of generating the static electricity in the lower substrate 101. If the lower substrate is formed of plastic so that the static electricity is generated, various wiring lines and driving elements on the lower substrate are damaged or the driving is affected due to the static electricity so that the display quality may be degraded. Instead, when the lower substrate 101 is formed of the transparent conducting oxide layer or the oxide semiconductor layer, the static electricity generated in the lower substrate 101 may be reduced and a configuration for blocking and discharging the static electricity may be simplified. Accordingly, in the display device 100 according to the exemplary embodiment of the present disclosure, the lower substrate 101 is formed of any one of the transparent conducting oxide layer or the oxide semiconductor having a low possibility of generating the static electricity. By doing this, the damage or the display quality degradation due to the static electricity may be reduced.

Further, in the display device 100 according to the exemplary embodiment of the present disclosure, the lower substrate 101 is formed of one of the transparent conducting oxide and the oxide semiconductor to reduce the permeation of the moisture or oxygen of the outside into the display device 100 by means of the lower substrate 101. When the lower substrate 101 is formed of the transparent conducting oxide layer or the oxide semiconductor, the lower substrate 101 is formed in the vacuum environment so that the foreign material generation possibility is significantly low. Further, even though the foreign material is generated, the size of the foreign material is very small so that the permeation of the moisture and oxygen into the display device 100 may be reduced. Accordingly, in the display device 100 according to the example embodiment of the present disclosure, the lower substrate 101 is formed of a transparent conducting oxide or the oxide semiconductor having a low possibility of generating the foreign materials and an excellent moisture permeation performance. By doing this, the reliability of the light emitting diode OLED including an organic layer and the display device 100 may be improved.

In the display device 100 according to the example embodiment of the present disclosure, the lower substrate 101 is formed of any one of a transparent conducting oxide and an oxide semiconductor to attach a barrier film which is thin and cheap below the lower substrate 101. When the lower substrate is formed of a material having a low moisture permeation performance, for example, plastic, the moisture permeability may be supplemented by attaching a high performance barrier film which is thick and expensive. However, in the display device 100 according to the example embodiment of the present disclosure, the lower substrate 101 is formed of a transparent conducting oxide or an oxide semiconductor having an excellent moisture permeation performance so that a thin and cheap barrier film may be attached below the lower substrate 101. Accordingly, in the display device 100 according to the exemplary embodiment of the present disclosure, the lower substrate 101 is configured by any one of the transparent conducting oxide or the oxide semiconductor having an excellent moisture permeation performance to reduce the manufacturing cost of the display device 100.

Further, in the display device 100 according to the exemplary embodiment of the present disclosure, the lower substrate 101 is formed of any one of a transparent conducting oxide and an oxide semiconductor to perform a laser lift off (LLO) process. When the display device 100 is manufactured, a temporary substrate TS in which a sacrificial layer SCL is formed is attached below the lower substrate 101 and then the pixel unit 120 may be formed on the lower substrate 101. For example, the sacrificial layer SL may use a hydrogenated amorphous silicon or an amorphous silicon which is hydrogenated and doped with impurities. After completing the manufacturing of the display device 100, when the laser is irradiated from the lower portion of the temporary substrate SUB, hydrogen of the sacrificial layer SL is dehydrogenated and the sacrificial layer SL and the temporary substrate SUB may be separated from the lower substrate 101. At this time, the transparent conducting oxide and the oxide semiconductor are materials which may perform the LLO process with the sacrificial layer SL and the temporary substrate SUB. Therefore, even though the lower substrate 101 is formed of any one of the transparent conducting oxide or the oxide semiconductor, the lower substrate 101 may be easily separated from the temporary substrate SUB. Accordingly, in the display device 100 according to the exemplary embodiment of the present disclosure, the lower substrate 101 is configured by any one of the transparent conducting oxide layer or the oxide semiconductor which may perform the LLO process. Therefore, the display device 100 may be easily manufactured with the existing process and equipment.

In the meantime, when the lower substrate configured by one of the transparent conducting oxide layer or oxide semiconductor is used as described above, the lower substrate may be disposed in the entire area of the display device for the LLO process. That is, the lower substrate may be disposed in the entire active area and non-active area of the display device. At this time, the lower substrate is disposed so as to extend to an outermost area of the display device. However, when the lower substrate is disposed in the outermost area, the lower substrate is easily cracked, and thus, damaged by the external impact. Therefore, when an external force is applied to a boundary of the upper substrate having a higher rigidity, an area of the pad unit and the gate driver disposed on the lower substrate which corresponds to the upper substrate is cracked and damaged. Therefore, the reliability of the display device may be degraded. Moreover, when the crack is generated on the lower substrate, the crack may propagate to the other component and specifically, when the crack propagates to the wiring lines or the circuit configuration which configure the pad unit and the gate driver disposed on the lower substrate, the driving failure may be caused.

In the display device 100 according to the exemplary embodiment of the present disclosure, the outer pattern 102 is disposed so as to enclose the lower substrate 101 to configure the outer pattern 102 with an organic material. Accordingly, during the LLO process, the LLO process may be easily performed through the temporary substrate SUB through which laser light transmits and the outer pattern 102 which absorbs the laser. At this time, the outer pattern 102 may be configured by a material having a high absorptivity to the laser. Therefore, the laser which passes through the temporary substrate SUB is absorbed onto the outer pattern 102 so that the temporary substrate SB and the outer pattern 102 may be easily separated during the process of removing the temporary substrate SUB.

Therefore, in the display device 100 according to the exemplary embodiment of the present disclosure, the lower substrate 101 which is configured by an inorganic material may not be disposed at the outer peripheral portion of the display device 100. Further, the lower substrate 101 may not be disposed in an area corresponding to the boundary of the upper substrate 140. Therefore, the lower substrate 101 may not be damaged or cracked by the impact from the outside of the display device 100 and a stress applied to the boundary of the upper substrate 140. Accordingly, in the display device 100 according to the exemplary embodiment of the present disclosure, the reliability may be improved and the driving failure due to the crack may also be reduced.

In the display device 100 according to the exemplary embodiment of the present disclosure, the outer pattern 102 is disposed below the pad unit P to suppress the damage of the pad unit P. The pad unit P may be attached to the plurality of flexible films 160 by means of a conductive adhesive member 180. At this time, when a rigid material is disposed below the pad unit P, there may be a problem in that the conductive adhesive member 180 and the flexible film 160 may be damaged by the physical impact which is applied to the pad unit P during the LLO process. Accordingly, in the display device 100 according to the exemplary embodiment of the present disclosure, the outer pattern 102 formed of an organic material having a relatively lower modulus is disposed below the pad unit P to suppress the damage caused on the conductive adhesive member 180 and the flexible film 160 by the external force.

Further, among the plurality of link lines 190, the second line pattern 192 which is diagonally disposed to be curved at angles different from the first line pattern 191 and the third line pattern 193 is disposed to overlap the outer pattern 102. Therefore, the second line pattern 192 which is relatively vulnerable to the stress may not be damaged or cracked by the impact from the outside of the display device 100 and the stress applied to the boundary of the upper substrate 140. Accordingly, in the display device 100 according to the exemplary embodiment of the present disclosure, the damage of the plurality of link lines 190 due to the crack may be reduced.

Further, in the display device 100 according to the exemplary embodiment of the present disclosure, a colored polyimide is used for the outer pattern 102 to reduce the cost and the time of the manufacturing process of the display device 100. In the case of the polyimide, in order to implement transparent polyimide with an opaque material, an additive may be added. Therefore, in order to implement the polyimide to have a transparent color, the time and the cost are additionally requested. In the meantime, in the display device 100 according to the example embodiment of the present disclosure, the outer pattern 102 is disposed in the non-active area NA so that it is not necessary to display the screen through the outer pattern 102. Accordingly, in the display device 100 according to the example embodiment of the present disclosure, there is no problem to form the outer pattern 102 with an opaque polyimide so that the process cost and the time for forming the outer pattern 102 may be reduced.

Further, in the display device 100 according to the example embodiment of the present disclosure, the outer pattern 102 is disposed below the gate driver GD to reduce the parasitic capacitance. When the conductive material is disposed below the gate driver GD, there is a problem in that the parasitic capacitance between the gate driver GD and the conductive material is increased so that the reliability of the gate driver GD may be degraded. Therefore, in the display device 100 according to the example embodiment of the present disclosure, an outer pattern 102 configured by a material which is not conductive is disposed below the gate driver GD to suppress the parasitic capacitance generated in the gate driver GD and stably drive the gate driver GD.

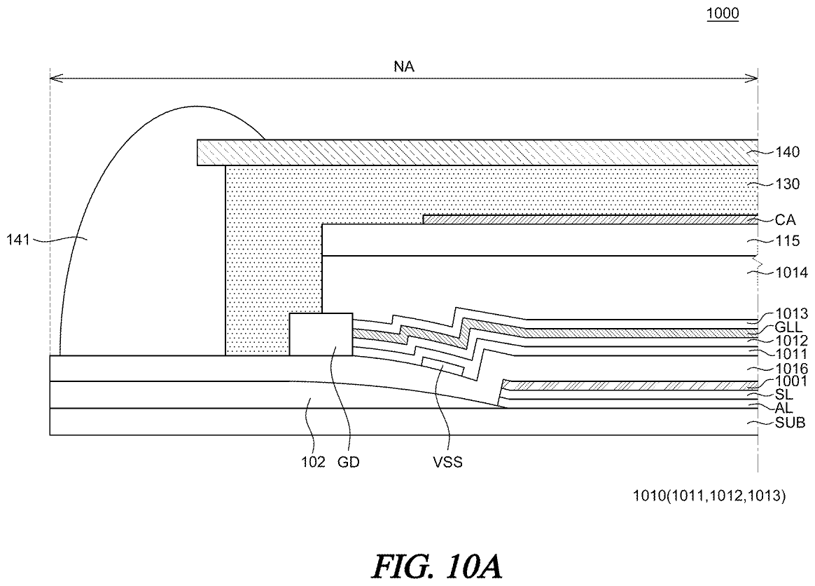

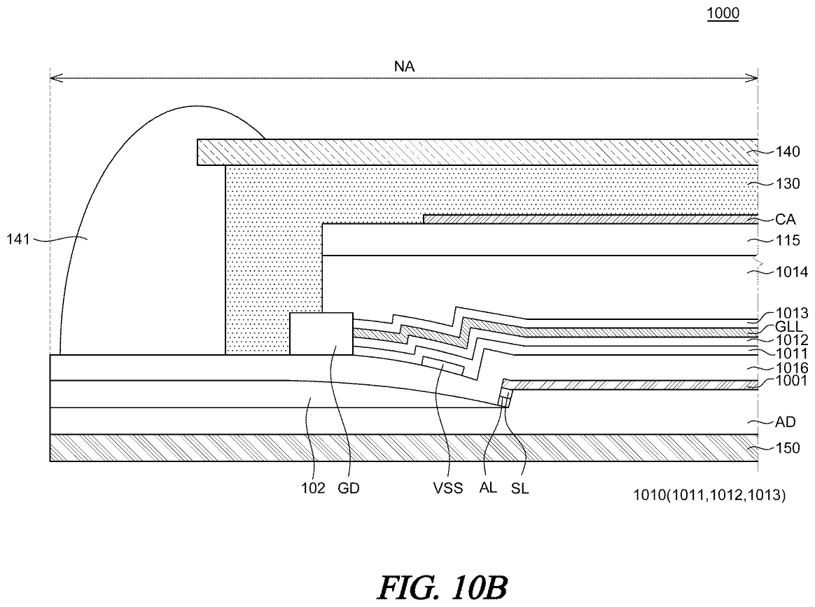

FIG. 10A is a cross-sectional view for explaining a manufacturing process of a display device according to another example embodiment of the present disclosure. FIG. 10B is a cross-sectional view of a display device according to another example embodiment of the present disclosure. Except for an auxiliary layer AL, a sacrificial layer SL, a lower substrate 1001, a lower buffer layer 1016, a low potential power line VSS, an inorganic layer 1010, and a planarization layer 1014, the other configurations of a display device 1000 of FIGS. 10A and 10B are substantially the same as those of the display device 100 of FIGS. 1 to 9B. Therefore, a redundant description will be omitted.

First, referring to FIG. 10A, the outer pattern 102 is disposed on the temporary substrate SUB. The outer pattern 102 may be disposed with a thickness of 1700 Å to 5500 Å in an area overlapping the edge of the temporary substrate SUB and include an inclined top surface having a thickness which is reduced as it is closer to the center portion of the temporary substrate SUB.

The auxiliary layer AL and the sacrificial layer SL are disposed on the temporary substrate SUB. The auxiliary layer AL and the sacrificial layer SL may be disposed so as to overlap a part of the outer pattern 102. At this time, the auxiliary layer AL and the sacrificial layer SL may be disposed to have a narrow area overlapping the inclined top surface of the outer pattern 102 so that an exposed area of the inclined top surface of the outer pattern 102 is relatively large.

The lower substrate 1001 is disposed on the sacrificial layer SL. The lower substrate 1001 may be disposed with the same area so as to fully overlap the sacrificial layer SL. Therefore, the lower substrate 1001 is disposed in the center portion of the temporary substrate SB and may be disposed so as to have a narrow area overlapping the inclined top surface of the outer pattern 102.

The lower buffer layer 1016 is disposed on the lower substrate 1001. The lower buffer layer 1016 may be disposed so as to overlap the lower substrate 1001 and the outer pattern 102. The lower buffer layer 1016 may be formed along top surfaces of the lower substrate 1001 and the outer pattern 102 disposed therebelow.

A low potential power line VSS is disposed on the lower buffer layer 1016. The low potential power line VSS may be disposed at the outside more than the end of the lower substrate 1001 to overlap the outer pattern 102, but does not overlap the lower substrate 1001.

The inorganic layer 1010 and the gate link line GLL are disposed on the lower buffer layer 1016 and the low potential power line VSS. The inorganic layer 1010 and the gate link line GLL may have top surfaces curved along top surfaces of the outer pattern 102, the lower substrate 1001, and the lower buffer layer 1016.

The planarization layer 1014 is disposed on the inorganic layer 1010.

The planarization layer 1014 may have a flat top surface to relieve a step generated in the inorganic layer 1010 and the lower buffer layer 1016 disposed therebelow.

Next, the lower substrate 1001 and the temporary substrate SUB may be separated from each other by means of the LLO process.

During the LLO process, the lower substrate 1001 and the outer pattern 102 disposed at the outside of the lower substrate 1001 may be separated from the temporary substrate SUB.

When the above-described LLO process is completed, as illustrated in FIG. 10B, the lower substrate 1001 and the outer pattern 102 remain. During the LLO process, a part of the sacrificial layer SL and the auxiliary layer AL which overlaps the outer pattern 102 remains to be disposed on the outer pattern 102. However, in a part which does not overlap the outer pattern 102, the sacrificial layer SL and the auxiliary layer AL disposed below the lower substrate 1001 may be removed together during a process of removing the temporary substrate SUB.

Next, the polarizer 150 is disposed below the outer pattern 102 and the lower substrate 1001.

Referring to FIG. 10B, the adhesive member AD is disposed on bottom surfaces of the outer pattern 102 and the lower substrate 1001. Therefore, the adhesive member AD may protrude to an area from which the sacrificial layer SL is removed.

In the display device 1000 according to another example embodiment of the present disclosure, the outer pattern 102 configured by the organic material is disposed so as to enclose the lower substrate 1001 to easily separate the temporary substrate SUB and the outer pattern 102 during the LLO process. Therefore, in the display device 1000 according to another example embodiment of the present disclosure, the lower substrate 1001 which is configured by an inorganic material may not be disposed in an area corresponding to a boundary of the outer peripheral portion of the display device 1000 and the upper substrate 140. Accordingly, in the display device 1000 according to still another example embodiment of the present disclosure, the reliability may be improved and the driving failure due to the crack may also be reduced.

Further, in the display device 1000 according to still another example embodiment of the present disclosure, the outer pattern 102 formed of an organic material having a relatively lower modulus is disposed below the pad unit P to suppress the damage caused on the conductive adhesive member 180 and the flexible film 160 by the external force.

Further, in the display device 1000 according to another example embodiment of the present disclosure, a colored polyimide is used for the outer pattern 102 to reduce the cost and the time of the manufacturing process of the display device 1000.

Further, in the display device 1000 according to another example embodiment of the present disclosure, an outer pattern 102 configured by a material which is not conductive is disposed below the gate driver GD to suppress the parasitic capacitance generated in the gate driver GD and stably drive the gate driver GD.

Further, in the display device 1000 according to another example embodiment of the present disclosure, the outer pattern 102 is disposed below the low potential power line VSS to reduce the parasitic capacitance. When the conductive material is disposed below the low potential power line VSS, the parasitic capacitance between the low potential power line VSS and the conductive material is increased so that the low potential power which is transmitted to the low potential power line VSS may fluctuate. Therefore, in the display device 1000 according to another example embodiment of the present disclosure, the outer pattern 102 which is configured by a material which is not conductive is disposed below the low potential power line VSS to reduce the parasitic capacitance generated in the low potential power line VSS.

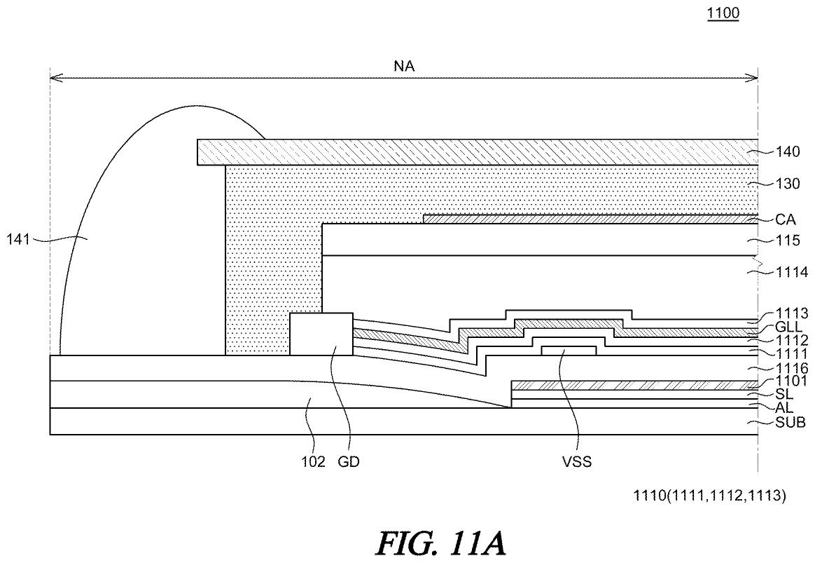

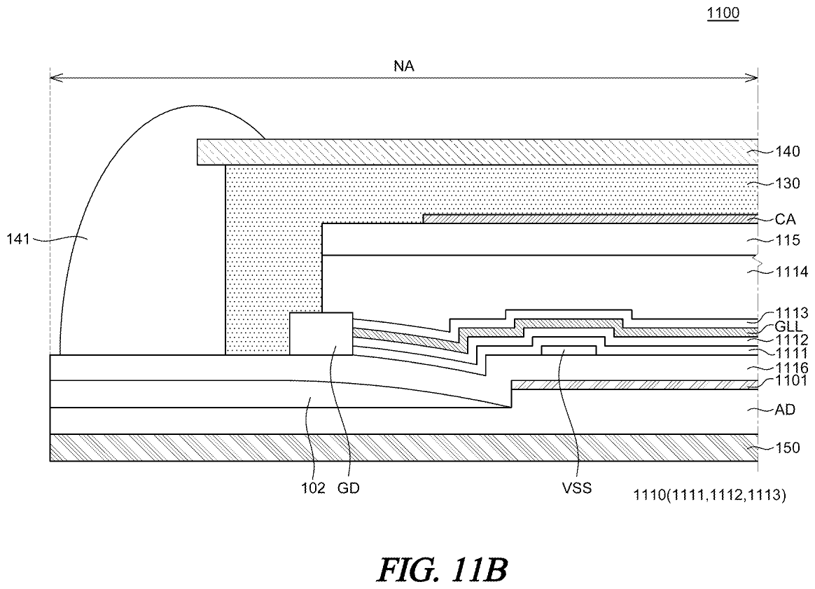

FIG. 11A is a cross-sectional view for explaining a manufacturing process of a display device according to still another example embodiment of the present disclosure. FIG. 11B is a cross-sectional view of a display device according to still another example embodiment of the present disclosure. Except for an auxiliary layer AL, a sacrificial layer SL, a lower substrate 1101, a lower buffer layer 1116, a low potential power line VSS, an inorganic layer 1110, and a planarization layer 1114, the other configurations of a display device 1100 of FIGS. 11A and 11B are substantially the same as those of the display device 100 of FIGS. 1 to 9B. Therefore, a redundant description will be omitted.

First, referring to FIG. 11A, the outer pattern 102 is disposed on the temporary substrate SUB. The outer pattern 102 may be disposed with a thickness of 1700 Å to 5500 Å in an area overlapping the edge of the temporary substrate SUB and include an inclined top surface having a thickness which is reduced as it is closer to the center portion of the temporary substrate SUB.

The auxiliary layer AL and the sacrificial layer SL are disposed on the temporary substrate SUB. Side surfaces of the auxiliary layer AL and the sacrificial layer SL may be disposed on the same plane as a side surface of the outer pattern 102. That is, the auxiliary layer AL and the sacrificial layer SL may be disposed at the outside of the outer pattern 102 so as not to overlap the outer pattern 102.

The lower substrate 1101 is disposed on the sacrificial layer SL. The lower substrate 1101 may be disposed with the same area so as to fully overlap the sacrificial layer SL. Therefore, the lower substrate 1101 is disposed in the center portion of the temporary substrate SUB and may be disposed at the inside more than the end of the outer pattern 102 so that the outer pattern 102 is disposed so as to enclose the end of the lower substrate 1101. Therefore, the lower substrate 1101 may be disposed on the temporary substrate SUB, the auxiliary layer AL, and the sacrificial layer SL disposed on the flat top surface.

The lower buffer layer 1116 is disposed on the lower substrate 1101. The lower buffer layer 1116 may be disposed so as to overlap the lower substrate 1101 and the outer pattern 102. The lower buffer layer 1116 may be formed along top surfaces of the lower substrate 1101 and the outer pattern 102 disposed therebelow. Therefore, the lower buffer layer 1116 may be disposed to have a flat top surface on the edges of the lower substrate 1101 and the outer pattern 102 and may be disposed with a curved top surface on the inclined top surface of the outer pattern 102.

A low potential power line VSS is disposed on the lower buffer layer 1116. The low potential power line VSS may be disposed so as not to overlap the outer pattern 102 and disposed on the flat top surface of the lower substrate 1101.

The inorganic layer 1110 and the gate link line GLL are disposed on the lower buffer layer 1116 and the low potential power line VSS. The inorganic layer 1110 and the gate link line GLL may have top surfaces curved along top surfaces of the outer pattern 102, the lower substrate 1101, and the lower buffer layer 1116.

The planarization layer 1114 is disposed on the inorganic layer 1110. The planarization layer 1114 may have a flat top surface to relieve a step generated in the inorganic layer 1110 and the lower buffer layer 1116 disposed therebelow.

Next, the lower substrate 1101 and the temporary substrate SUB may be separated from each other by means of the LLO process.

During the LLO process, the lower substrate 1101 and the outer pattern 102 disposed at the outside of the lower substrate 1101 may be separated from the temporary substrate SUB.

When the above-described LLO process is completed, as illustrated in FIG. 11B, the lower substrate 1101 and the outer pattern 102 remain. During the LLO process, a part of the sacrificial layer SL and the auxiliary layer AL which overlaps the outer pattern 102 remains to be disposed on the outer pattern 102. However, in a part which does not overlap the outer pattern 102, the sacrificial layer SL and the auxiliary layer AL disposed below the lower substrate 1101 may be removed together during a process of removing the temporary substrate SUB.

Next, the polarizer 150 is disposed below the outer pattern 102 and the lower substrate 1101.

Referring to FIG. 11B, the adhesive member AD may be disposed on bottom surfaces of the outer pattern 102 and the lower substrate 1101. Therefore, the adhesive member AD may protrude to an area from which the sacrificial layer SL is removed.

In the display device 1100 according to still another example embodiment of the present disclosure, the outer pattern 102 configured by the organic material is disposed so as to enclose the lower substrate 1101 to easily separate the temporary substrate SUB and the outer pattern 102 during the LLO process.

Therefore, in the display device 1100 according to still another example embodiment of the present disclosure, the lower substrate 1101 which is configured by an inorganic material may not be disposed in an area corresponding to a boundary of the outer peripheral portion of the display device 1100 and the upper substrate 140. Accordingly, in the display device 1100 according to still another example embodiment of the present disclosure, the reliability may be improved and the driving failure due to the crack may also be reduced.

Further, in the display device 1100 according to still another example embodiment of the present disclosure, the outer pattern 102 formed of an organic material having a relatively lower modulus is disposed below the pad unit P to suppress the damage caused on the conductive adhesive member 180 and the flexible film 160 by the external force.

Further, in the display device 1100 according to still another example embodiment of the present disclosure, a colored polyimide is used for the outer pattern 102 to reduce the cost and the time of the manufacturing process of the display device 1100.

Further, in the display device 1100 according to still another example embodiment of the present disclosure, the outer pattern 102 configured by a material which is not conductive is disposed below the gate driver GD to suppress the parasitic capacitance generated in the gate driver GD and stably drive the gate driver GD.

Further, in the display device 1100 according to still another example embodiment of the present disclosure, the lower substrate 1101 is disposed at the outside of the outer pattern 102 to dispose the low potential power line VSS and the inorganic layer 1110 disposed on the lower substrate 1101 and the gate link line GLL on a flat top surface. Therefore, the crack of the inorganic layer disposed on the wavy top surface may be suppressed. Accordingly, in the display device 1100 according to still another example embodiment of the present disclosure, cracks or damages of the low potential power line VSS, the inorganic layer 1110, and the gate link line GLL are suppressed to improve the reliability of the display device 1100.

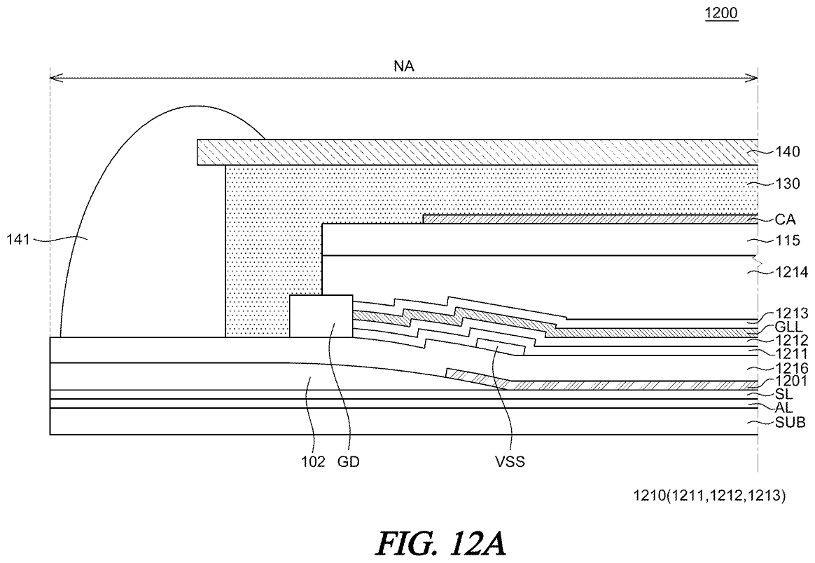

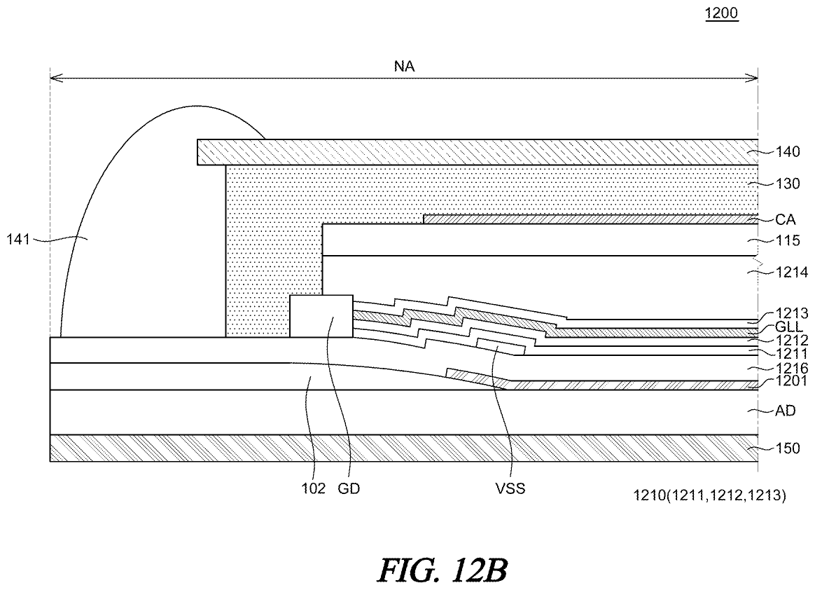

FIG. 12A is a cross-sectional view for explaining a manufacturing process of a display device according to still another example embodiment of the present disclosure. FIG. 12B is a cross-sectional view of a display device according to still another example embodiment of the present disclosure. Except for an auxiliary layer AL, a sacrificial layer SL, a lower substrate 1201, a lower buffer layer 1216, a low potential power line VSS, an inorganic layer 1210, and a planarization layer 1214, the other configurations of a display device 1200 of FIGS. 12A and 12B are substantially the same as those of the display device 100 of FIGS. 1 to 9B. Therefore, a redundant description will be omitted.

First, referring to FIG. 12A, the auxiliary layer AL and the sacrificial layer SL are disposed on the temporary substrate SUB. The auxiliary layer AL and the sacrificial layer SL may be disposed with the same area as the temporary substrate SUB to overlap the entire surface of the temporary substrate SUB.

The outer pattern 102 is disposed on the auxiliary layer AL and the sacrificial layer SL. The outer pattern 102 may be disposed with a thickness of 1700 Å to 5500 Å in an area overlapping the edges of the temporary substrate SUB, the auxiliary layer AL, and the sacrificial layer SL and include an inclined top surface having a thickness which is reduced as it is closer to the center portions of the temporary substrate SUB, the auxiliary layer AL, and the sacrificial layer SL.

The lower substrate 1201 is disposed on the outer pattern 102, the auxiliary layer AL, and the sacrificial layer SL. The lower substrate 1201 may be formed to have a smaller area than the temporary substrate SUB. Therefore, a part of the lower substrate 1201 may be disposed so as to be in contact with a part of the outer pattern 102. For example, the lower substrate 1201 may be disposed so as to overlap the auxiliary layer AL and the sacrificial layer SL in an area which does not overlap the outer pattern 102 but may be disposed so as to overlap the outer pattern 102 in an area overlapping the outer pattern 102.

The lower buffer layer 1216 is disposed on the lower substrate 1201. The lower buffer layer 1216 may be disposed so as to overlap the lower substrate 1201 and the outer pattern 102. The lower buffer layer 1216 may be formed along top surfaces of the lower substrate 1201 and the outer pattern 102 disposed therebelow.

The low potential power line VSS is disposed on the lower buffer layer 1216. The low potential power line VSS may be disposed between the gate driver GD and the active area AA in the non-active area NA. The low potential power line VSS is disposed at the inside more than the lower substrate 1201 to overlap the lower substrate 1201. The inorganic layer 1210 and the gate link line GLL are disposed on the lower buffer layer 1216 and the low potential power line VSS. The inorganic layer 1210 and the gate link line GLL may have top surfaces curved along top surfaces of the outer pattern 102, the lower substrate 1201, and the lower buffer layer 1216.

The planarization layer 1214 is disposed on the inorganic layer 1210. The planarization layer 1214 may have a flat top surface to relieve a step generated in the inorganic layer 1210 and the lower buffer layer 1216 disposed therebelow.

Next, the lower substrate 1201 and the temporary substrate SUB may be separated from each other by means of the LLO process.

During the LLO process, the lower substrate 1201 and the outer pattern 102 disposed at the outside of the lower substrate 101 may be separated from the temporary substrate SUB.

When the above-described LLO process is completed, as illustrated in FIG. 12B, the lower substrate 1201 and the outer pattern 102 remain. During the LLO process, all the sacrificial layer SL and the auxiliary layer AL disposed below the lower substrate 1201 may be removed during the process of removing the temporary substrate SUB.

Next, the polarizer 150 is disposed below the outer pattern 102 and the lower substrate 1201.

Referring to FIG. 12B, the adhesive member AD may be disposed on bottom surfaces of the outer pattern 102 and the lower substrate 1201. Therefore, the adhesive member AD may be disposed in an area from which the sacrificial layer SL is removed to have a flat top surface.

In the display device 1200 according to still another example embodiment of the present disclosure, the outer pattern 102 configured by the organic material is disposed so as to enclose the lower substrate 1201 to easily separate the temporary substrate SUB and the outer pattern 102 during the LLO process.

Therefore, in the display device 1200 according to still another example embodiment of the present disclosure, the lower substrate 1201 which is configured by an inorganic material may not be disposed in an area corresponding to a boundary of the outer peripheral portion of the display device 1200 and the upper substrate 140. Accordingly, in the display device 1200 according to still another example embodiment of the present disclosure, the reliability may be improved and the driving failure due to the crack may also be reduced.

Further, in the display device 1200 according to still another example embodiment of the present disclosure, the outer pattern 102 formed of an organic material having a relatively lower modulus is disposed below the pad unit P to suppress the damage caused on the conductive adhesive member 180 and the flexible film 160 by the external force.

Further, in the display device 1200 according to still another example embodiment of the present disclosure, a colored polyimide is used for the outer pattern 102 to reduce the cost and the time of the manufacturing process of the display device 1200.

Further, in the display device 1200 according to still another example embodiment of the present disclosure, an outer pattern 102 configured by a material which is not conductive is disposed below the gate driver GD to suppress the parasitic capacitance generated in the gate driver GD and stably drive the gate driver GD.

Further, in the display device 1200 according to still another example embodiment of the present disclosure, the auxiliary layer AL and the sacrificial layer SL are disposed so as to overlap the top surface of the temporary substrate SUB to easily perform the LLO process. That is, other component is not disposed between the temporary substrate SUB and the auxiliary layer AL and the sacrificial layer SL so that the sacrificial layer SL absorbs most of energy of the laser during the LLO process so that the sacrificial layer SL and the lower substrate 1201 may be easily separated. Therefore, the LLO process may be easily performed in the display device 1200 according to still another example embodiment of the present disclosure.

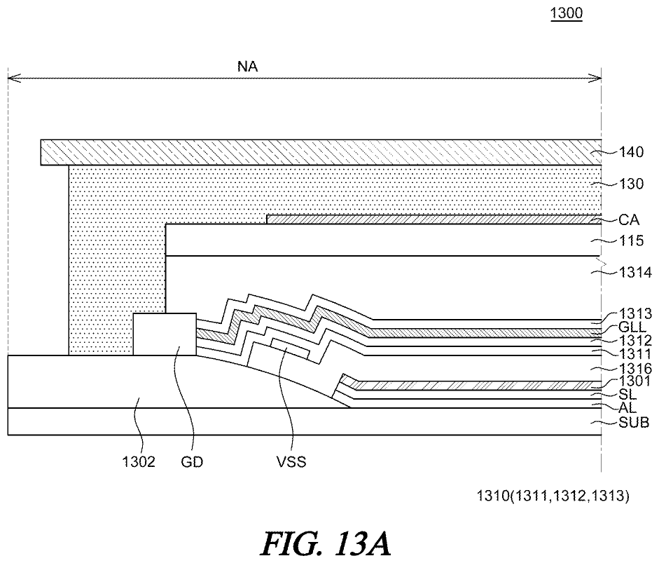

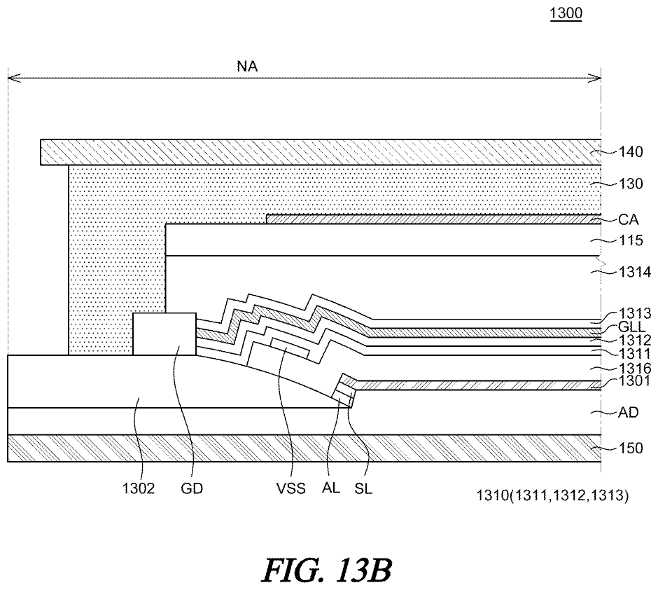

FIG. 13A is a cross-sectional view for explaining a manufacturing process of a display device according to still another example embodiment of the present disclosure. FIG. 13B is a cross-sectional view of a display device according to still another example embodiment of the present disclosure. Except that an auxiliary layer AL, a sacrificial layer SL, a lower substrate 1301, an outer pattern 1302, a lower buffer layer 1316, a low potential power line VSS, a driver GD, an inorganic layer 1310, and a planarization layer 1314 are different and a seal member is not disposed, the other configurations of a display device 1300 of FIGS. 13A and 13B are substantially the same as those of the display device 100 of FIGS. 1 to 9B. Therefore, a redundant description will be omitted.

First, referring to FIG. 13A, the outer pattern 1302 is disposed on the temporary substrate SUB. The outer pattern 1302 may be disposed with a thickness of approximately 5500 Å in an area overlapping the edge of the temporary substrate SUB and include an inclined top surface having a thickness which is reduced as it is closer to the center portion of the temporary substrate SUB.

The auxiliary layer AL and the sacrificial layer SL are disposed on the temporary substrate SUB. The auxiliary layer AL and the sacrificial layer SL may be disposed so as to overlap a part of the outer pattern 1302. At this time, the auxiliary layer AL and the sacrificial layer SL may be disposed in a part of the inclined top surface of the outer pattern 1302 so that an exposed area of the inclined top surface of the outer pattern 1302 is relatively large.

The lower substrate 1301 is disposed on the auxiliary layer AL and the sacrificial layer SL. The lower substrate 1301 may be disposed with the same area so as to fully overlap the sacrificial layer SL. Therefore, the lower substrate 1301 is disposed in the center portion of the temporary substrate SUB and may be disposed so as to have a narrow area overlapping the inclined top surface of the outer pattern 1302.

The lower buffer layer 1316 is disposed on the lower substrate 1301. The lower buffer layer 1316 may be disposed so as to overlap the lower substrate 1301 and the outer pattern 1302. At this time, the end of the lower buffer layer 1316 may be disposed at the inside more than the upper substrate 140. For example, the lower buffer layer 1316 may be disposed to cover an end of the lower substrate 1301. Therefore, the end of the lower buffer layer 1316 may be disposed on the inclined top surface of the outer pattern 1302, but is not limited thereto.

The gate driver GD may be disposed on the outer pattern 1302. The gate driver GD is disposed at the outside more than the end of the lower buffer layer 1316 to overlap the outer pattern 1302 and not to overlap the lower substrate 1316.

The low potential power line VSS is disposed on the lower buffer layer 1316. The low potential power line VSS is disposed at the outside more than the end of the lower substrate 1301 to overlap the lower substrate 1302, but not to overlap the lower substrate 1301.

The inorganic layer 1310 and the gate link line GLL are disposed on the lower buffer layer 1316 and the low potential power line VSS. The inorganic layer 1310 and the gate link line GLL may have top surfaces curved along top surfaces of the outer pattern 1302, the lower substrate 1301, and the lower buffer layer 1316.

The planarization layer 1314 is disposed on the inorganic layer 1310. The planarization layer 1314 may have a flat top surface to relieve a step generated in the inorganic layer 1310 and the lower buffer layer 1316 disposed therebelow.

Next, the lower substrate 1301 and the temporary substrate SUB may be separated from each other by means of the LLO process.

Next, the polarizer 150 is disposed below the outer pattern 1302 and the lower substrate 1301.

During the LLO process, the lower substrate 1301 and the outer pattern 1302 disposed at the outside of the lower substrate 1301 may be separated from the temporary substrate SUB.

When the above-described LLO process is completed, as illustrated in FIG. 13B, the lower substrate 1301 and the outer pattern 1302 remain.

During the LLO process, a part of the sacrificial layer SL and the auxiliary layer AL which overlaps the outer pattern 1302 remains to be disposed on the outer pattern 1302. However, in a part of the sacrificial layer SL and the auxiliary layer AL which does not overlap the outer pattern 1302, the sacrificial layer SL and the auxiliary layer AL disposed below the lower substrate 1301 may be removed together during a process of removing the temporary substrate SUB.

Next, the polarizer 150 is disposed below the outer pattern 1302 and the lower substrate 1301.

Referring to FIG. 13B, the adhesive member AD may be disposed on bottom surfaces of the outer pattern 1302 and the lower substrate 1301. Therefore, the adhesive member AD may protrude to an area from which the sacrificial layer SL is removed.

In the display device 1300 according to still another example embodiment of the present disclosure, the outer pattern 1302 configured by the organic material is disposed so as to enclose the lower substrate 1301 to easily separate the temporary substrate SUB and the outer pattern 1302 during the LLO process.

Therefore, in the display device 1300 according to still another example embodiment of the present disclosure, the lower substrate 1301 which is configured by an inorganic material may not be disposed in an area corresponding to a boundary of the outer peripheral portion of the display device 1300 and the upper substrate 140. Accordingly, in the display device 1300 according to still another example embodiment of the present disclosure, the reliability may be improved and the driving failure due to the crack may also be reduced.

Further, in the display device 1300 according to still another example embodiment of the present disclosure, the outer pattern 1302 formed of an organic material having a relatively lower modulus is disposed below the pad unit P to suppress the damage caused on the conductive adhesive member 180 and the flexible film 160 by the external force.

Further, in the display device 1300 according to still another example embodiment of the present disclosure, a colored polyimide is used for the outer pattern 1302 to reduce the cost and the time of the manufacturing process of the display device 1300.

Further, in the display device 1300 according to still another example embodiment of the present disclosure, an outer pattern 1302 configured by a material which is not conductive is disposed below the gate driver GD to suppress the parasitic capacitance generated in the gate driver GD and stably drive the gate driver GD.

Further, in the display device 1300 according to still another example embodiment of the present disclosure, the lower buffer layer 1316 is disposed at the inside more than the upper substrate 140 and the thickness of the outer pattern 1302 is disposed so as to correspond to the thickness of the lower buffer layer 1316 and the lower substrate 1301. Therefore, the top surface of the outer pattern 1302 may be disposed in a position corresponding to a top surface of the lower buffer layer 1316. Therefore, an inclination angles of the wavy top surface disposed on the lower buffer layer 1316 and the outer pattern 1302 are reduced to suppress the crack of the inorganic layer disposed on the wavy top surface. Accordingly, in the display device 1300 according to still another example embodiment of the present disclosure, cracks or damages of the low potential power line VSS, the inorganic layer 1310, and the gate link line GLL are suppressed to improve the reliability of the display device 1300.

Further, in the display device 1300 according to still another example embodiment of the present disclosure, a seal member disposed at the outside of the upper substrate 140 and the adhesive layer 130 is removed to reduce the bezel area. Generally, in the display device, a seal member was disposed at the outer peripheral portion of the display device to maintain a shape of the outer peripheral portion of the display device. For example, when the substrate disposed at the outermost side of the display device is disposed to have a thin thickness, an outer peripheral area of the display device may be naturally bent. Therefore, in order to suppress the bending phenomenon of the display device, the seal member which supports the outer peripheral area of the display device was disposed. When the seal member is disposed, the non-active area is increased as much as an area in which the seal member is disposed so that it is restricted to reduce the bezel. However, in the display device 1300 according to still another example embodiment of the present disclosure, the thickness of the outer pattern 1302 disposed in the outer peripheral area of the display device is increased so that the outer pattern 1302 may support the outer peripheral portion of the display device 1300. Therefore, a flat shape of the outer peripheral area of the display device 1300 may be maintained without having a separate support structure so that the necessity for placing the seal member may be removed. Further, when the seal member is disposed, the bezel area may be reduced.

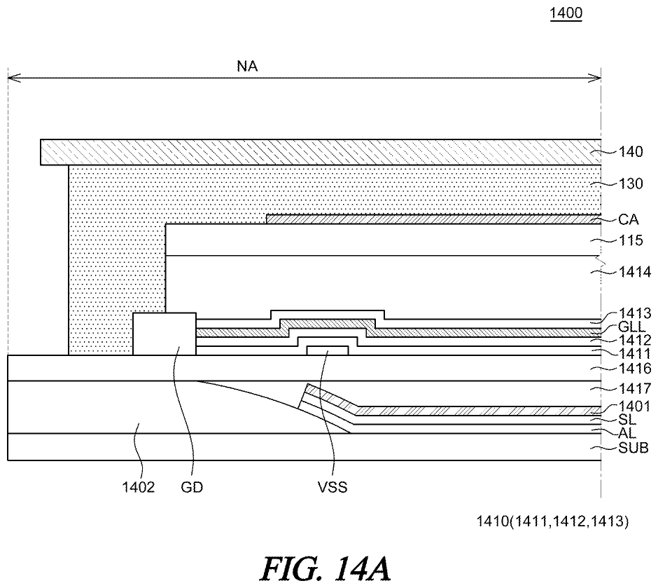

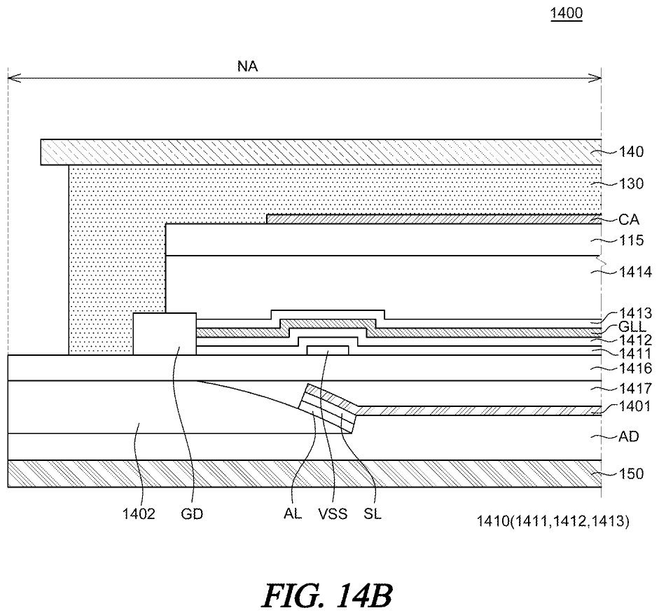

FIG. 14A is a cross-sectional view for explaining a manufacturing process of a display device according to still another example embodiment of the present disclosure. FIG. 14B is a cross-sectional view of a display device according to still another example embodiment of the present disclosure. Except that an auxiliary layer AL, a sacrificial layer SL, a lower substrate 1401, an outer pattern 1402, a lower buffer layer 1416, a low potential power line VSS, a driver GD, an inorganic layer 1410, and a planarization layer 1414 are different and a step compensation layer 1417 is added, the other configurations of a display device 1400 of FIGS. 14A and 14B are substantially the same as those of the display device 100 of FIGS. 13A and 13B. Therefore, a redundant description will be omitted.

First, referring to FIG. 14A, the outer pattern 1402 is disposed on the temporary substrate SUB. The outer pattern 1402 may be disposed with a thickness of approximately 10000 Å in an area overlapping the edge of the temporary substrate SUB and include an inclined top surface having a thickness which is reduced as it is closer to the center portion of the temporary substrate SUB.

The auxiliary layer AL and the sacrificial layer SL are disposed on the temporary substrate SUB. The auxiliary layer AL and the sacrificial layer SL are formed with an area smaller than the temporary substrate SUB to be disposed in a center portion of the temporary substrate SUB and overlap a part of the outer pattern 1402.

The lower substrate 1401 is disposed on the auxiliary layer AL and the sacrificial layer SL. The lower substrate 1401 may be disposed with the same area so as to fully overlap the sacrificial layer SL.

The step compensation layer 1417 is disposed on the lower substrate 1401. The step compensation layer 1417 may be disposed so as to overlap the lower substrate 1401 and the outer pattern 1402. At this time, the step compensation layer 1417 may be disposed on the lower substrate 1401 to have a thickness of approximately 8000 Å.

The step compensation layer 1417 may be configured by an inorganic film or an organic film, such as polyimide.

The step compensation layer 1417 may planarize a lower portion of the inorganic layer 1400 on the lower substrate 1401 and the outer pattern 1402. That is, the step compensation layer 1417 may have a flat top surface on the lower substrate 1401 and the outer pattern 1402. Referring to FIGS. 14A and 14B, an end of the step compensation layer 1417 may be disposed on the outer pattern 1402. The step compensation layer 1417 may be disposed so as to be in contact with a part of the lower substrate 1401 and the outer pattern 1402. However, it is not limited thereto, and the end of the outer pattern 1402 may be disposed on the same plane as the end of the outer pattern 1402.

The lower buffer layer 1416 is disposed on the outer pattern 1402 and the step compensation layer 1417. Therefore, a top surface of the step compensation layer 1417 may be in contact with a bottom surface of the lower buffer layer 1416. The lower buffer layer 1416 may be formed along top surfaces of the outer pattern 1402 and the step compensation layer 1417 disposed therebelow. Therefore, the lower buffer layer 1416 may be disposed to have a flat top surface.

The gate driver GD and the low potential power line VSS are disposed on the lower buffer layer 1416. The gate driver GD and the low potential power line VSS may be disposed on the flat top surface of the lower buffer layer 1416.

The inorganic layer 1410 and the gate link line GLL are disposed on the lower buffer layer 1416 and the low potential power line VSS. The inorganic layer 1410 and the gate link line GLL may be disposed along a top surface of the lower buffer layer 1416.

The planarization layer 1414 is disposed on the inorganic layer 1410. The planarization layer 1414 may have a flat top surface to relieve a step generated in the inorganic layer 1410 and the lower buffer layer 1416 disposed therebelow.

Next, the lower substrate 1401 and the temporary substrate SUB may be separated from each other by means of the LLO process.

Next, the polarizer 150 is disposed below the outer pattern 1402 and the lower substrate 1401.

During the LLO process, the lower substrate 1401 and the outer pattern 1402 disposed at the outside of the lower substrate 1401 may be separated from the temporary substrate SUB.

When the above-described LLO process is completed, as illustrated in FIG. 14B, the lower substrate 1401 and the outer pattern 1402 remain.

During the LLO process, a part of the sacrificial layer SL and the auxiliary layer AL which overlaps the outer pattern 1402 remains to be disposed on the outer pattern 1402. However, in a part of the sacrificial layer SL and the auxiliary layer AL which does not overlap the outer pattern 1402, the sacrificial layer SL and the auxiliary layer AL disposed below the lower substrate 1401 may be removed together during a process of removing the temporary substrate SUB.

Next, the polarizer 150 is disposed below the outer pattern 1402 and the lower substrate 1401.

Referring to FIG. 14B, the adhesive member AD may be disposed on bottom surfaces of the outer pattern 1402 and the lower substrate 1401. Therefore, the adhesive member AD may protrude to an area from which the sacrificial layer SL is removed.

In the display device 1400 according to still another example embodiment of the present disclosure, the outer pattern 1402 configured by the organic material is disposed so as to enclose the lower substrate 1401 to easily separate the temporary substrate SUB and the outer pattern 1402 during the LLO process.

Therefore, in the display device 1400 according to still another example embodiment of the present disclosure, the lower substrate 1401 which is configured by an inorganic material may not be disposed in an area corresponding to a boundary of the outer peripheral portion of the display device 1400 and the upper substrate 140. Accordingly, in the display device 1400 according to still another example embodiment of the present disclosure, the reliability may be improved and the driving failure due to the crack may also be reduced.

Further, in the display device 1400 according to still another example embodiment of the present disclosure, the outer pattern 1402 formed of an organic material having a relatively lower modulus is disposed below the pad unit P to suppress the damage caused on the conductive adhesive member 180 and the flexible film 160 by the external force.

Further, in the display device 1400 according to still another example embodiment of the present disclosure, a colored polyimide is used for the outer pattern 1402 to reduce the cost and the time of the manufacturing process of the display device 1400.

Further, in the display device 1400 according to still another example embodiment of the present disclosure, an outer pattern 1402 configured by a material which is not conductive is disposed below the gate driver GD to suppress the parasitic capacitance generated in the gate driver GD and stably drive the gate driver GD.

Further, in the display device 1400 according to still another example embodiment of the present disclosure, the step compensation layer 1417 is disposed below the lower buffer layer 1416 to planarize a step generated on top surfaces of the outer pattern 1402 and the lower substrate 1401. In the display device 1400 according to still another example embodiment of the present disclosure, the lower potential power line VSS and the inorganic layer 1410 disposed on the lower buffer layer 1416 and the gate link line GLL are disposed on the flat top surface. Therefore, the crack or damage of the low potential power line VSS, the inorganic layer 1410, and the gate link line GLL may be suppressed and the reliability of the display device 1400 may be improved.

Further, in the display device 1400 according to still another example embodiment of the present disclosure, the outer pattern 1402 is disposed to be thick to support the outer peripheral portion of the display device 1400. Therefore, the seal member disposed at the outside of the upper substrate 140 and the adhesive layer 130 may be removed so that the bezel area may be reduced.

Further, in the display device 1400 according to still another example embodiment of the present disclosure, the step compensation layer 1417 is disposed above the lower substrate 1401 to planarize a step generated on top surfaces of the outer pattern 1402 and the lower substrate 1401. Therefore, the lower potential power line VSS and the inorganic layer 1410 disposed on the lower buffer layer 1416 and the gate link line GLL are disposed on the flat top surface. Therefore, the crack or damage of the low potential power line VSS, the inorganic layer 1410, and the gate link line GLL may be suppressed to improve the reliability of the display device 1400.

The example embodiments of the present disclosure can also be described as follows:

According to an aspect of the present disclosure, a display device comprising a lower substrate which includes an active area including a plurality of sub pixels and a non-active area enclosing the active area, and is formed of one of transparent conducting oxide and an oxide semiconductor, an outer pattern which is disposed so as to enclose an outer periphery of the lower substrate and is formed of an organic material, an inorganic layer disposed on the lower substrate and the outer pattern, and a plurality of light emitting diodes on the inorganic layer in the plurality of sub pixels.

The display device may further comprise a gate driver which may be disposed so as to overlap the outer pattern in the non-active area.

The display device may further comprise a low potential power line which is disposed between the gate driver and the active area in the non-active area, the low potential power line may be disposed so as to overlap the lower substrate.

The display device may further comprise a low potential power line which is disposed between the gate driver and the active area in the non-active area, the low potential power line may be disposed so as to overlap the outer pattern at the outside of the lower substrate.

The display device may further comprise a pad unit disposed in the non-active area, the pad unit may be disposed so as to overlap the outer pattern.

The outer pattern may be formed of polyimide (PI).

The outer pattern may overlap a part of the lower substrate.

The outer pattern may include an inclined top surface so that a thickness is reduced as it is closer to a center portion of the lower substrate.

An end of the lower substrate may be disposed on the inclined top surface of the outer pattern.

The display device may further comprise a sacrificial layer which is disposed between a part of the lower substrate and the outer pattern, and includes amorphous silicon.

The display device may further comprise an auxiliary layer disposed between the outer pattern and the sacrificial layer, the auxiliary layer is configured by silicon nitride.

A part of the lower substrate may be in contact with a part of the outer pattern.

The outer pattern may be disposed so as to enclose an end of the lower substrate.

The display device may further comprise a buffer layer disposed on a part of the lower substrate and on a part of the outer pattern on the lower substrate.

The display device may further comprise an upper substrate disposed on the inorganic layer and the light emitting diode, an end of the buffer layer is disposed at the outside more than an end of the upper substrate.

The display device may further comprise an upper substrate disposed on the inorganic layer and the light emitting diode, an end of the buffer layer is disposed inside more than an end of the upper substrate.

An end of the lower buffer layer may be disposed on an inclined top surface of the outer pattern.

The display device may further comprise a step compensation layer which planarizes a lower portion of the inorganic layer on the lower substrate.

An end of the step compensation layer may be disposed on the outer pattern.

A top surface of the step compensation layer may be in contact with a bottom surface of the buffer layer and the step compensation layer is disposed so as to be in contact with a part of the lower substrate and the outer pattern.

The display device may further comprise an upper substrate disposed on the inorganic layer and the plurality of light emitting diodes, an end of the upper substrate is disposed on the outer pattern.

The display device may further comprise a seal member disposed so as to enclose a side surface of the upper substrate, the seal member is disposed on the outer pattern.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a lower substrate which includes an active area including a plurality of sub pixels and a non-active area enclosing the active area, and is formed of one of a transparent conducting oxide and an oxide semiconductor;
an outer pattern which encloses an outer periphery of the lower substrate and is formed of an organic material;
an inorganic layer disposed on the lower substrate and the outer pattern; and
a plurality of light emitting diodes on the inorganic layer in the plurality of sub pixels.

2. The display device according to claim 1, further comprising:
a gate driver which overlaps the outer pattern in the non-active area.

3. The display device according to claim 2, further comprising:
a low potential power line which is disposed in the non-active area between the gate driver and the active area,
wherein the low potential power line overlaps the lower substrate.

4. The display device according to claim 2, further comprising:
a low potential power line which is disposed in the non-active area between the gate driver and the active area,
wherein the low potential power line overlaps the outer pattern at the outside of the lower substrate.

5. The display device according to claim 1, further comprising:
a pad unit disposed in the non-active area,
wherein the pad unit overlaps the outer pattern.

6. The display device according to claim 1, wherein the outer pattern is formed of polyimide (PI).

7. The display device according to claim 1, wherein the outer pattern overlaps a part of the lower substrate.

8. The display device according to claim 1, wherein the outer pattern includes an inclined top surface, and a thickness of the outer pattern deceases as it is closer to a center portion of the lower substrate.

9. The display device according to claim 8, wherein an end of the lower substrate is disposed on the inclined top surface of the outer pattern.

10. The display device according to claim 9, further comprising:
a sacrificial layer which is disposed between a part of the lower substrate and the outer pattern, and includes amorphous silicon.

11. The display device according to claim 10, further comprising:
an auxiliary layer disposed between the outer pattern and the sacrificial layer,
wherein the auxiliary layer includes silicon nitride.

12. The display device according to claim 9, wherein a part of the lower substrate is in contact with a part of the outer pattern.

13. The display device according to claim 1, wherein the outer pattern encloses an end of the lower substrate.

14. The display device according to claim 1, further comprising:
a buffer layer disposed on a part of the lower substrate and on a part of the outer pattern on the lower substrate.

15. The display device according to claim 14, further comprising:
an upper substrate disposed on the inorganic layer and the light emitting diode,
wherein an end of the buffer layer extends beyond an end of the upper substrate.

16. The display device according to claim 14, further comprising:
an upper substrate disposed on the inorganic layer and the light emitting diode,
wherein an end of the buffer layer is disposed inside an end of the upper substrate.

17. The display device according to claim 16, wherein the outer pattern includes an incline top surface and an end of the lower buffer layer is disposed on the inclined top surface of the outer pattern.

18. The display device according to claim 14, further comprising:
a step compensation layer which planarizes a lower portion of the inorganic layer on the lower substrate.

19. The display device according to claim 18, wherein an end of the step compensation layer is disposed on the outer pattern.

20. The display device according to claim 18, wherein a top surface of the step compensation layer is in contact with a bottom surface of the buffer layer and the step compensation layer is in contact with a part of the lower substrate and the outer pattern.

21. The display device according to claim 1, further comprising:
an upper substrate disposed on the inorganic layer and the plurality of light emitting diodes,
wherein an end of the upper substrate is disposed on the outer pattern.

22. The display device according to claim 21, further comprising:
a seal member that encloses a side surface of the upper substrate,
wherein the seal member is disposed on the outer pattern.
